(19) United States
(12) Patent Application Publication
(10) Pub. No.: US 2026/0050283 A1
(43) Pub. Date: Feb. 19, 2026

(54) BIAS GENERATION FOR COMMON DRAIN BIDIRECTIONAL SWITCH DRIVER

(71) Applicant: TEXAS INSTRUMENTS INCORPORATED, Dallas, TX (US)

(72) Inventors: Orlando Lazaro, Cary, NC (US); Timothy Merkin, Princeton, TX (US); Michael Lueders, Freising (DE); Ujwal Radhakrishna, San Jose, CA (US); Fei Zhou, Plano, TX (US)

(21) Appl. No.: 19/283,199

(22) Filed: Jul. 28, 2025

Related U.S. Application Data
(60) Provisional application No. 63/682,968, filed on Aug. 14, 2024.

(51) Int. Cl. G05F 3/20; G05F 1/46; H03K 17/06; H03K 17/22; H03K 17/687

(52) U.S. Cl. CPC G05F 3/205; G05F 1/462; H03K 17/063; H03K 17/223; H03K 17/6871

(57) ABSTRACT

A circuit includes a first driver, a second driver, and a bias generator. First driver has a first bias terminal, a first reference terminal, a first driver input, and a first driver output. The second driver has a second bias terminal, a second reference terminal, a second driver input, and a second driver output. The bias generator has a first input, a second input, a first bias output, and a second bias output, the first input coupled to the first reference terminal, the second input coupled to the second reference terminal, the first bias output coupled to the first bias terminal, and the second bias output coupled to the second bias terminal, wherein the bias generator is configurable to generate, based on a supply voltage, a first bias voltage at the first bias output and a second bias voltage at the second bias output.

### CROSS-REFERENCE TO RELATED APPLICATION

This application claims the benefit of and priority to U.S. Provisional Application No. 63/682,968, filed Aug. 14, 2024, entitled “Bias Generation for Common Drain Bidirectional Switch Driver,” which is assigned to the assignee hereof and is hereby incorporated by reference in its entirety for all purposes.

### BACKGROUND

A bidirectional switch can support bidirectional current flow between two switch terminals when it is in the enabled (“ON”) state, and can provide bidirectional voltage blocking between the two switch terminals when it is in the disabled (“OFF”) state. A bidirectional switch may include one or more transistors coupled in series between the two switch terminals, and the voltage(s) at the control terminal(s) (e.g., gate(s)) of the one or more transistors can set the enabled/disabled state of the bidirectional switch.

### SUMMARY

This Summary is provided to introduce examples of disclosed concepts in a simplified form, which are further described below in the Detailed Description including the drawings provided.

According to certain aspects, a circuit may include a first driver, a second driver, and a bias generator. First driver has a first bias terminal, a first reference terminal, a first driver input, and a first driver output, and the first driver output configurable to couple to a first gate of the first transistor. The second driver has a second bias terminal, a second reference terminal, a second driver input, and a second driver output. The bias generator has a first input, a second input, a first bias output, and a second bias output, the first input coupled to the first reference terminal, the second input coupled to the second reference terminal, the first bias output coupled to the first bias terminal, and the second bias output coupled to the second bias terminal, wherein the bias generator is configurable to generate, based on a supply voltage, a first bias voltage at the first bias output and a second bias voltage at the second bias output.

According to certain aspects, a circuit may include a pair of transistors, a first driver, a second driver, and a bias generator. The pair of transistors has a common drain, a first source, a second source, a first gate, and a second gate. The first driver has a first bias terminal, a first reference terminal, a first driver input, and a first driver output, the first reference terminal coupled to the first source, and the first driver output coupled to the first gate. The second driver has a second bias terminal, a second reference terminal, a second driver input, and a second driver output, the second reference terminal coupled to the second source, and the second driver output coupled to the second gate. The bias generator has a first input, a second input, a first bias output, and a second bias output, the first input coupled to the first source, the second input coupled to the second source, the first bias output coupled to the first bias terminal, and the second bias output coupled to the second bias terminal, wherein the bias generator is configurable to generate, based on a supply voltage, a first bias voltage at the first bias output and a second bias voltage at the second bias output.

According to certain aspects, a circuit may include a first input port, a first output port, and a second output port. The circuit may also include a first bidirectional switch and a second bidirectional switch. The first bidirectional switch is coupled between the first input port and the first output port, the first bidirectional switch including a first switch driver, a second switch driver, and a first bias generator configurable to generate, based on a first supply voltage, a first bias voltage for the first switch driver and a second bias voltage for the second switch driver. The second bidirectional switch is coupled between the first input port and the second output port, the second bidirectional switch including a third switch driver, a fourth switch driver, and a second bias generator configurable to generate, based on a second supply voltage, a third bias voltage for the third switch driver and a fourth bias voltage for the fourth switch driver.

The foregoing summary outlines rather broadly various features of examples of the present disclosure so that the following detailed description may be better understood. Additional features and advantages of such examples will be described hereinafter. This summary is neither intended to identify key or essential features of the claimed subject matters, nor is it intended to be used in isolation to determine the scope of the claimed subject matters. The subject matters should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1A is a schematic diagram of an example of a bidirectional switch including two transistors having a common drain region.

FIG. 1B is a cross-sectional view of an example of a monolithic bidirectional switch.

FIG. 2 is a schematic diagram of an example of a circuit including a bidirectional switch and circuits for controlling the bidirectional switch.

FIG. 3 is a block diagram of an example of a circuit including a bidirectional switch and circuits for controlling the bidirectional switch.

FIG. 4 is a block diagram of an example of a circuit including a bidirectional switch and circuits for controlling the bidirectional switch.

FIG. 5 is a schematic diagram of an example of a circuit including a bidirectional switch and circuits for controlling the bidirectional switch.

FIG. 6 is a schematic diagram of another example of a circuit including a bidirectional switch and circuits for controlling the bidirectional switch.

FIG. 7 is a block diagram of an example of a circuit including a bidirectional switch and circuits for controlling the bidirectional switch.

FIG. 8A is a schematic diagram of an example of a circuit including a bidirectional switch and circuits for controlling the bidirectional switch.

FIG. 8B illustrates an example of an operation of the circuit of FIG. 9A.

FIG. 9 is a block diagram of an example of a circuit including a bidirectional switch and circuits for controlling the bidirectional switch.

FIG. 10 is a schematic diagram of an example of a circuit including a bidirectional switch and circuits for controlling the bidirectional switch.

FIG. 11 is a schematic diagram of an example of a circuit including a bidirectional switch and circuits for controlling the bidirectional switch.

FIG. 12 is a schematic diagram of an example of a circuit including a bidirectional switch and circuits for controlling the bidirectional switch.

FIG. 13 is a schematic diagram of an example of a circuit including a bidirectional switch and circuits for controlling the bidirectional switch.

FIG. 14A is a schematic diagram of an example of a matrix converter with bias supply sharing.

FIG. 14B is a schematic diagram of an example of a matrix converter with additional bias supply sharing.

FIG. 15 is a schematic diagram of an example of a bidirectional switch.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to bidirectional switches. In some examples, a circuit may include a transistor-based bidirectional switch and two drivers for controlling the transistor-based bidirectional switch. The transistor-based bidirectional switch may include, for example, two gallium nitride (GaN)-based high electron mobility transistors (HEMTs) sharing a common drain region. The two drivers may be biased (e.g., powered) by a bias circuit that may generate respective bias voltages (e.g., supply voltages) for the two drivers using a single voltage supply/voltage source, rather than using two separate voltage supplies.

A GaN-based HEMT may include a heterojunction formed by a channel layer (e.g., a GaN layer) and a barrier layer (e.g., an aluminum gallium nitride (AlGaN) layer). High-density two-dimensional electron gas (2DEG) can be formed at the heterojunction to function as a conductive channel. For example, the 2DEG can have a sheet charge density greater than about 10¹³ cm⁻², and thus can have a low static on-state resistance. GaN-based HEMTs are attractive for high frequency and high power applications due to, for example, the high breakdown field, high electron mobility, low static resistance, and high thermal conductivity of GaN-based HEMTs. For example, due to the possibility of current flowing from drain to source and vice versa in a switched-on HEMT, and the possibility of blocking the current flow from drain to source in a switched-off HEMT, GaN-based HEMTs can be used for bidirectional power switching. Due to the lateral device structure and the nonexistence of body diodes in GaN-based HEMTs, it can be relatively easy to fabricate monolithic bidirectional switches implemented using GaN-based HEMTs. In addition, due to the low static on-state resistance of GaN-based HEMTs, GaN-based bidirectional switches can have low power loss and low voltage drop.

In some examples, a GaN-based bidirectional switch may include two HEMTs connected back-to-back (e.g., with the drains of the two HEMTs connected together) to form a dual-gate bidirectional switch having share a common drain region, the source of the first HEMT forms a first terminal of the bidirectional switch, and the source of the second HEMT forms a second terminal of the bidirectional switch. Since the voltage rating of a HEMT may depend on the gate-to-drain separation, using the common drain region can provide the requisite gate-to-drain separation for a particular voltage rating in both directions, while reducing the total distance between the two terminals of the bidirectional switch and thus the on-state resistance and power loss of the bidirectional switch. For example, the first HEMT of the bidirectional switch may be initially in the off state with its gate and source having a same high voltage, the second HEMT may be the blocking transistor, and the gate of the second HEMT may be the gate for switching the bidirectional switch on or off, such that the common drain region between the gates of the two HEMTs may be used to block the high voltage from reaching the second terminal of the bidirectional switch. Similarly, the second HEMT of the bidirectional switch may be initially in the off state with its gate and source having a same high voltage, and the gate of the first HEMT may be the gate for switching the bidirectional switch on or off, such that the common drain region between the gates of the two HEMTs may be used to block the high voltage from reaching the first terminal. Therefore, the distance between the gate and the corresponding source of each HEMT can be short, while the bidirectional switch can still achieve high voltage blocking in both directions due to the sharing of the common drain region. As such, a monolithic bidirectional switch having a common drain region and dual gates can have a reduced cell pitch (and thus a smaller device size) and a lower on-state resistance (Ron), while achieving high voltage blocking.

Since the sources of the two transistors of the bidirectional switch may be coupled to the two switch terminals, which may be at different voltage levels before the bidirectional switch is turned on (enabled), different voltage levels may be applied to the gates of the two transistors in order to turn on the bidirectional switch. As such, the gate of each transistor in the bidirectional switch may be controlled by a respective driver. Each driver may have a driver input, a reference terminal (e.g., coupled to the source of a transistor of the bidirectional switch), a bias terminal (e.g., a power supply terminal), and a driver output coupled to a control terminal (e.g., a gate) of the transistor-based bidirectional switch. A bias circuit may be used to set an appropriate bias voltage level at the bias terminal of the driver so that the output of the driver can properly turn on or off a corresponding transistor of the bidirectional switch. Since the reference terminals of the two drivers are coupled to the two terminals of the bidirectional switch that are at different voltage levels before the bidirectional switch is turned on, the bias terminals of the two drivers may be at different voltage levels for the outputs of the two drivers to properly turn on or off the two transistors of the bidirectional switch. In some bidirectional switch control circuits, two isolated voltage sources may be used to apply different voltage levels to the bias terminals of the two drivers. Such bidirectional switch control circuits may be less efficient, more expensive, and bulky.

In some examples disclosed herein, the drivers for two control terminals of a bidirectional switch may receive respective bias voltages from a bias generator that generates the respective bias voltages using a single voltage supply/voltage source. The bias generator may have a first input, a second input, a first bias output, and a second bias output. The first input may be coupled to a first switch terminal (e.g., the source of a first transistor) of the bidirectional switch (which may be coupled to the reference terminal of a first driver). The second input may be coupled to a second switch terminal (e.g., the source of a second transistor) of the bidirectional switch (which may be coupled to the reference terminal of a second driver). The first bias output may be coupled to the bias terminal of the first driver, and the second bias output may be coupled to the bias terminal of the second driver.

In some examples, the bias generator may include a maximum voltage selector coupled to the first and second inputs and having an output. The bias generator may also include an isolated voltage source having a first (e.g., negative) supply terminal coupled to the output of the maximum voltage selector, a first bootstrap circuit coupled between a second (e.g., positive) supply terminal of the isolated voltage source and the first bias output, and a second bootstrap circuit coupled between the second supply terminal of the isolated voltage source and the second bias output. In one example, the maximum voltage selector may include a third transistor and a fourth transistor that may have a common drain terminal coupled to the output of the maximum voltage selector.

In some examples, the bias generator may include a minimum voltage selector coupled to the first and second inputs and having an output. The bias generator may also include an isolated voltage source having a first (e.g., negative) supply terminal coupled to the output of the minimum voltage selector, a first bootstrap circuit coupled between a second (e.g., positive) supply terminal of the isolated voltage source and the first bias output, and a second bootstrap circuit coupled between the second supply terminal of the isolated voltage source and the second bias output. In one example, the minimum voltage selector may include a first switch between the first input and the output of the minimum voltage selector, and a second switch between the second input and the output of the minimum voltage selector.

In some examples, the bias generator may include a charge transfer circuit coupled between the first and second bias outputs. In some examples, the charge transfer circuit may include an auxiliary bidirectional switch. The auxiliary bidirectional switch may be controlled by two auxiliary drivers that receive the same bias voltage and the same reference voltage as the first driver or the second driver. In one example, the bias generator may also include a first voltage source (e.g., a first bootstrap capacitor or isolated voltage supply) coupled between the first input and the first bias output, a first startup circuit coupled between the second bias output and the first input and including a first output terminal coupled to the first bias output, a second voltage source (e.g., a second bootstrap capacitor or isolated voltage supply) coupled between the second input and the second bias output, and a second startup circuit coupled between the first bias output and the second input and including a second output terminal coupled to the second bias output. In another example, the bias generator may also include a voltage supply including a positive terminal and a negative terminal coupled to the first input, a first bootstrap capacitor coupled between the first input and the first bias output, a first voltage regulator (e.g., a source follower) coupled between the positive terminal of the voltage supply and the first bias output, a second bootstrap capacitor coupled between the second input the second bias output, a second auxiliary bidirectional switch including a first terminal coupled to the positive terminal of the voltage supply, and a second voltage regulator (e.g., a source follower) coupled between a second terminal of the second auxiliary bidirectional switch and the second bias output.

In another example, the bias generator may include a first bootstrap capacitor or a first voltage source coupled between the first input and the first bias output, and a second bootsrap capacitor or a second voltage source coupled between the second input and the second bias output. The charge transfer circuit may include a first bidirectional switch and a first voltage regulator (e.g., a source follower) coupled between the first bias output and the second bias output, and a second bidirectional switch and a second voltage regulator (e.g., a source follower) coupled between the first bias output and the second bias output. The first bidirectional switch may be coupled to the first bias output, and the first voltage regulator may be coupled to the second bias output. The second bidirectional switch may be coupled to the second bias output, and the second voltage regulator may be coupled to the first bias output. The first bidirectional switch may include an enhancement-mode transistor and a depletion-mode transistor, where the enhancement-mode transistor may include a first gate terminal coupled to the first driver output via a charge pump capacitor, while the depletion-mode transistor may include a second gate terminal coupled to the second input of the bias generator (and the second terminal of the bidirectional switch).

In yet another example, the bias generator may include a voltage source coupled between the first input and the first bias output, and a bootstrap capacitor coupled between the second input and the second bias output. The charge transfer circuit may include an auxiliary bidirectional switch and a voltage regulator (e.g., a source follower) coupled between the first bias output and the second bias output, where the auxiliary bidirectional switch may be coupled to the first bias output, and the voltage regulator may be coupled to the second bias output. The charge transfer circuit may also include an auxiliary driver having a third bias terminal, a third reference terminal, and a third driver output, where the third bias terminal is coupled to the first bias output, and the third reference terminal is coupled to the first input. The auxiliary bidirectional switch may include an enhancement-mode transistor and a depletion-mode transistor, where the enhancement-mode transistor may have a first gate terminal coupled to the third driver output via a charge pump capacitor, and the depletion-mode transistor may have a second gate terminal coupled to the second input.

The bias generators disclosed herein may generate different bias voltages using a single voltage supply, may charge a voltage source (e.g., a bootstrap capacitor) for biasing a switch driver before startup when the voltage level of the voltage source is low, and may also replenish the voltage source after the bidirectional switch is turned on. In some examples, the bias generator may also include some other control circuits, such as control circuits that may control the charge transfer circuit and/or the voltage regulators to reduce leak or avoid current flow (and charge transfer) on paths having large voltage drops, so that power loss of the bias generator may be reduced.

Because the bias generation circuits disclosed herein may generate different bias voltages using a single voltage supply, the total number of voltage supplies used in a power switch matrix, such as a matrix converter, may be significantly reduced. In addition, the bias generation circuits disclosed herein may reduce power loss due to leakage and avoid power loss due to charge transfer on paths with large voltage drop. As a result, a system using the common-drain bidirectional switches and bias generation circuits disclosed herein can be less expensive and more efficient.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Some examples are described below in the context of an HEMT. Some examples may be implemented in enhancement-mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications. For the sake of illustration, some of the examples disclosed herein may focus on group-III nitride-based devices, such as GaN-based HEMTs. However, this disclosure is not limited to GaN-based HEMTs or other HEMTs, and can be applied to other devices formed by other semiconductor materials, such as silicon, other group-III nitride, or other III-V semiconductor materials.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

A bidirectional switch can support bidirectional current flow when it is turned on and can provide bidirectional voltage blocking when it is turned off. A bidirectional switch may be used, for example, as a bidirectional power switch for charger multiplexing, where the bidirectional switch may be turned on to charge a battery using a current from a power supply to the battery, or to provide a current from the battery to a load. The bidirectional switch may also be turned off to block current in either direction, for example, to avoid draining a charged battery or prevent one battery from charging another battery. A bidirectional switch may be implemented using two transistors connected back-to-back (e.g., with the drains connected together or with the sources connected together) to form a bidirectional switch having a common drain or a common source. The two transistors may include, for example, metal-oxide-semiconductor field effect transistors (MOSFETs) or HEMTs.

GaN-based HEMTs include heterostructures that may induce two-dimensional electron gas (2DEG) at the interface between two GaN-based materials having different bandgaps. In one example, the heterostructure may be formed by a GaN layer and an AlₓGa₍₁₋ₓ₎N layer, where x is the concentration of aluminum. The GaN layer may have a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer near the interface of the heterostructure to form a conductive channel in the GaN layer (which is thus referred to as the channel layer). Compared to silicon-based transistors, GaN-based transistors generally have high breakdown field, high electron mobility, low on-state resistance, high current, faster-switching speed, high thermal conductivity, and excellent reverse-recovery performance, and thus may be more suitable for applications where a low-loss and high-efficiency performance may be desired, such as power electronics (e.g., power switches).

A GaN-based transistor may include a gate structure positioned between a source structure and a drain structure. The drain structure may include a metal contact that may be coupled to the channel layer directly or indirectly (e.g., through tunneling) and may form an ohmic contact with the channel layer. The source structure may include a metal contact that may be coupled to the channel layer directly or indirectly and may form an ohmic contact with the channel layer. Depending on the architecture of the gate structure, a GaN-based transistor may be an enhancement-mode (E-mode) high electron mobility transistor (e-HEMT) or a depletion-mode (D-mode) high electron mobility transistors (d-HEMT). For example, the gate structure of an e-HEMT may include a p-GaN layer formed over the barrier layer, and a gate electrical contact (a metal electrode) formed on the p-GaN layer, which together form a p-GaN gate structure. The p-GaN layer of the gate structure may be doped with, for example, magnesium (Mg), which is an acceptor that can make the GaN layer p-type or p-doped. The p-GaN layer may deplete electrons in the 2DEG channel under the p-GaN gate structure, such that the conductive path between the source and gate may be disabled and thus the e-HEMT may be turned off when no gate drive voltage is applied to the gate electrical contact. When a positive voltage above a threshold voltage is applied to the gate electrical contact, the gate structure may attract electrons to replete the 2DEG under the gate structure, thereby turning on the e-HEMT. In contrast, the gate structure of a d-HEMT may include an insulator layer (e.g., a dielectric layer) over the barrier layer, and a gate electrical contact (e.g., a metal electrode) on the insulator layer. When no voltage signal is applied to the gate electrical contact, the 2DEG under the gate structure may not be depleted such that the conductive path in the channel layer between the drain structure and the source structure may be enabled even without a positive gate voltage. A d-HEMT can be turned off by applying a negative threshold voltage to the gate electrical contact to deplete electrons from the 2DEG under the gate structure. In some applications such as switch-mode power applications (e.g., power switches), e-HEMTs, rather than d-HEMTs, may be used in order to, for example, decrease leakage current, reduce power loss, simplify the driving circuit, and/or improve device stability.

High-density two-dimensional electron gas (2DEG) can be formed at the heterojunction of a GaN-based HEMT to function as a conductive channel. For example, the 2DEG can have a sheet charge density greater than about 10¹³ cm⁻², and thus can have a low static on-state resistance. GaN-based HEMTs are attractive for high frequency and high power applications due to, for example, the high breakdown field, high electron mobility, low static resistance, and high thermal conductivity of GaN-based HEMTs. For example, due to the possibility of current flowing from drain to source and vice versa in a switched-on HEMT, and the possibility of blocking the current flow from drain to source in a switched-off HEMT, GaN-based HEMTs can be used for bidirectional power switching. In addition, due to the low static on-state resistance of GaN-based HEMTs, GaN-based bidirectional switches can have low power loss and low voltage drop. In some examples, a GaN-based bidirectional switch may include two HEMTs connected back-to-back (e.g., with the drains of the two HEMTs connected together or the sources of the two HEMTs connected together) to form a dual-gate bidirectional switch having a common drain region, thereby reducing the total distance between the two terminals of the bidirectional switch and thus the on-state resistance of the bidirectional switch.

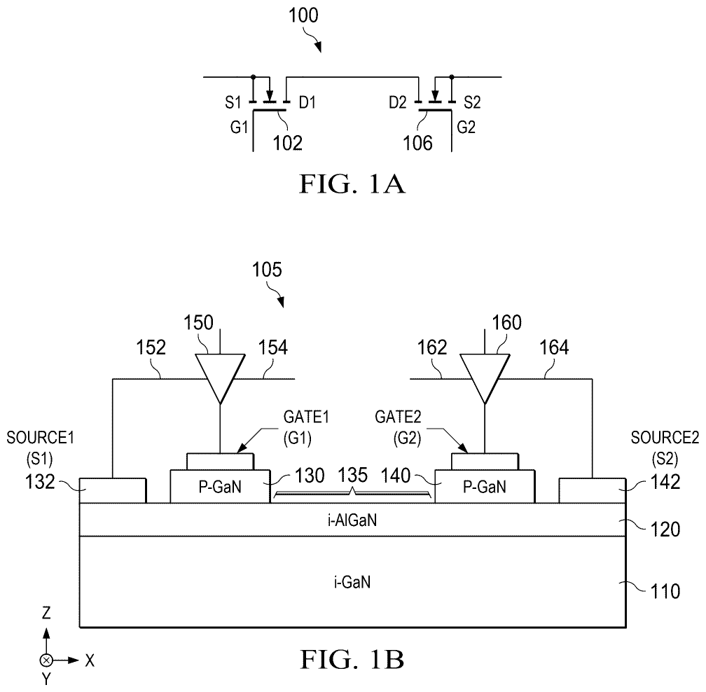

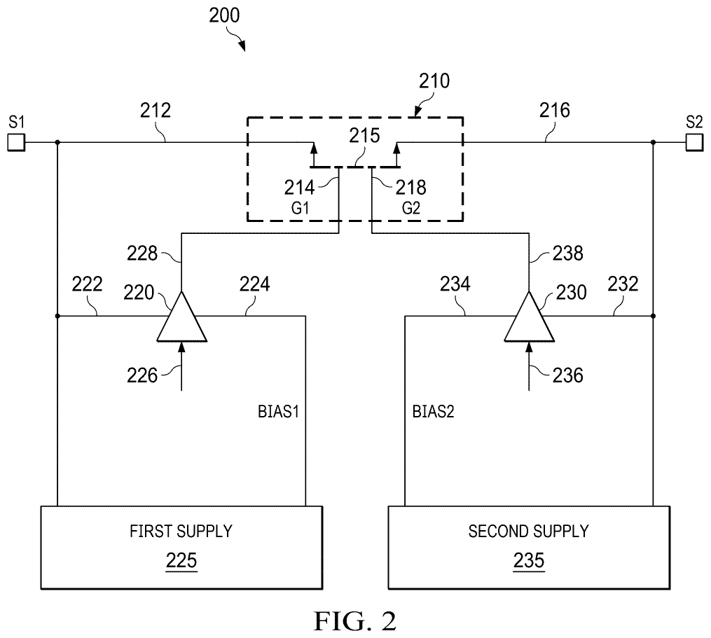

FIG. 1A is a schematic diagram of an example of a bidirectional switch 100 including two transistors connected back-to-back. In the example shown in FIG. 1A, bidirectional switch 100 may include a first transistor 102 (e.g., an N-MOSFET or an HEMT) and a second transistor 106 (e.g., an N-MOSFET or an HEMT) connected back-to-back to share a common drain. N-channel MOSFETs may have lower resistance than P-channel MOSFETs of similar sizes, and thus are more suitable for use in power switches. Transistors 102 and 106 may have a low voltage drop between the drain and source when the channel is turned on. When the gate voltage at gate G1 of first transistor 102 and the gate voltage at gate G2 of second transistor 106 are set properly (e.g., above the threshold voltage) to turn on both first transistor 102 and second transistor 106 so that bidirectional switch 100 is turned on (in an enabled state), a current may flow from source S1 of first transistor 102 to source S2 of second transistor 106 if the voltage level at source S1 is higher than the voltage level at source S2, or may flow from source S2 of second transistor 106 to source S1 of first transistor 102 if the voltage level at source S2 is higher than the voltage level at source S1. The total voltage drop at first transistor 102 and second transistor 106 that are turned on may be low (e.g., close to zero).

When only one of first transistor 102 and second transistor 106 is turned on, a current may be able to flow in one direction, but may be blocked from flowing in the opposite direction formed by the transistor that is turned off. For example, when first transistor 102 is turned on and second transistor 106 is turned off (e.g., by having gate and source of second transistor 106 having the same voltage), second transistor 106 may become diode-connected or otherwise operate like a diode. A current may be allowed to flow from source S2 to source S1 through the diode-connected second transistor 106, which operates similarly to a forward-biased diode, and the first transistor 102 (which is turned on), and the voltage drop between source S2 and source S1 may be close to the threshold voltage of second transistor 106 that is turned off, but a voltage at source S1 may be blocked from reaching source S2 by the diode-connected second transistor 106, which operates similarly to a reverse-biased diode in blocking that voltage. Similarly, when first transistor 102 is turned off (e.g., by having gate and source of second transistor 106 having the same voltage) and second transistor 106 is turned on, a current may be allowed to flow from source S1 to source S2 through the diode-connected first transistor 102, which operates similarly to a forward-biased diode, and second transistor 106 that is turned on, and the voltage drop between source S1 and source S2 may be close to the threshold voltage of first transistor 102, but a voltage at source S2 may be blocked from reaching source S1 by first transistor 102, which operates similarly to a reverse-biased diode in blocking that voltage.

When both first transistor 102 and second transistor 106 are turned off and thus bidirectional switch 100 is turned off (in a disabled state), no current (or an insignificant amount of current) may be allowed to flow between source S1 and source S2. For example, a current from source S1 to source S2 may be blocked by the reverse biased diode structure 108 formed by the turned-off second transistor 106, while a current from source S2 to source S1 may be blocked the turned-off first transistor 102.

As described above, compared to silicon-based transistors, GaN-based HEMTs may have high breakdown field, high electron mobility, low on-state resistance, high current, faster-switching speed, high thermal conductivity, and excellent reverse-recovery performance, and thus may be more suitable for applications where a low-loss and high-efficiency performance may be desired, such as power electronics or radio frequency (RF) circuits. A GaN-based HEMT may allow current to flow from the drain to source and vice versa when the HEMT is turned on (in the ON state), may block the current flow from the drain to source when the HEMT is turned off (in the OFF state), and may have lower static on-state resistance (and thus lower voltage drop and lower power loss) than MOSFETs due to, for example, the high electron mobility. Therefore, GaN-based HEMTs may be suitable for use in bidirectional switches and may offer higher switching speed and lower power loss and voltage drop. The nonexistence of body diodes in GaN-based HEMTs can also eliminate reverse recovery loss caused by body diodes, which can reduce switching loss. In addition, due to the lateral device structure, it can be relatively easy to fabricate monolithic bidirectional switches implemented using GaN-based HEMTs. In some examples, a GaN-based bidirectional switch may include two HEMTs connected back-to-back to form a dual-gate bidirectional switch having a common drain or a common source.

FIG. 1B is a cross-sectional view of an example of a monolithic dual-gate bidirectional switch 105, which may be an example of bidirectional switch 100 shown in FIG. 1A. Bidirectional switch 105 may be a bidirectional power switch implemented using GaN-based HEMTs. In the illustrated example, bidirectional switch 105 includes two enhancement-mode HEMTs that are connected back-to-back to share a common drain region 135. Bidirectional switch 105 may include a substrate (not shown), a channel layer 110 (e.g., including an undoped GaN layer) grown on the substrate, and a barrier layer 120 (e.g., including an undoped AlₓGa₍₁₋ₓ₎N layer) over channel layer 110. The substrate may include, for example, a bulk semiconductor substrate, a semiconductor-on-insulator (SOI) substrate, or another suitable substrate (e.g., a Qromis Substrate Technology (QST) substrate, a sapphire substrate, or another silicon-based substrate). The GaN material in channel layer 110 has a narrower bandgap than the AlₓGa₍₁₋ₓ₎N material in barrier layer 120. Due to the bandgap mismatch, large conduction-band offset, and spontaneous and piezoelectric polarization properties of the group-III nitride layers, highly-mobile 2DEG may be generated in channel layer 110 near the interface of the heterostructure to form a conductive channel in channel layer 110.

A first gate structure 130 and a second gate structure 140 may be formed over barrier layer 120. Each of first gate structure 130 and second gate structure 140 may include a p-GaN layer formed over barrier layer 120 and a gate electrical contact (e.g., a metal gate electrode) formed on the p-GaN layer, which together form a p-GaN gate structure. The p-GaN layer may be a GaN layer doped with, for example, magnesium (Mg). The p-GaN layer may deplete electrons in the 2DEG channel under the p-GaN gate structure, such that the path between the source and drain may be disabled when no gate drive voltage is applied to the gate electrical contact. When a positive voltage above the threshold voltage is applied to the gate electrical contact, the gate structure may attract electrons to replete the 2DEG under the gate structure, thereby turning on the enhancement-mode HEMT. A first source structure 132 and a second source structure 142 may be formed on or in barrier layer 120. The common drain of the two HEMTs may not need to be accessed, and thus there may not need to be a drain structure formed over barrier layer 120. The source and gate structures may be electrically isolated by one or more dielectric layers (not shown) and may be accessible through interconnects (not shown) formed in the dielectric layers.

In the example shown in FIG. 1B, first gate structure 130 of the first HEMT may be controlled by a first driver 150, while second gate structure 140 of the second HEMT may be controlled by a second driver 160. First driver 150 may have a reference terminal 152 coupled to first source structure 132 and may have a bias terminal 154 (e.g., a power supply terminal) coupled to a voltage source, so that the driver output of first driver 150 may have the appropriate voltage level with respect to first source structure 132 to properly turn on the first HEMT (e.g., when the voltage difference V_{GS} between the gate and the source is equal to or greater than the threshold voltage Vₜₕ) or turn off the first HEMT (e.g., when V_{GS}<Vₜₕ). Similarly, second driver 160 may have a reference terminal 164 coupled to second source structure 142 and may have a bias terminal 162 coupled to a voltage source, so that the driver output of second driver 160 may have the appropriate voltage level with respect to second source structure 142 to properly turn on the second HEMT (e.g., when V_{GS}≥Vₜₕ) or turn off the second HEMT (e.g., when V_{GS}<Vₜₕ).

As described above, when both the first HEMT and the second HEMT are turned on, bidirectional switch 105 may be turned on (in the enabled state) and may have low resistance and low voltage drop between first source structure 132 and second source structure 142. When only one of the first HEMT and the second HEMT is turned on, a current may be allowed to flow in one direction and there may be a voltage drop across bidirectional switch 105 due to the threshold voltage of the HEMT that is not turned on, and a current may not be allowed to flow in the opposite direction by the HEMT that is turned off. When both the first HEMT and the second HEMT are turned off, bidirectional switch 105 may be turned off (in the disabled state), and may block current flow in both directions because current may not be allowed to flow from the drain to the source of the HEMTs that are not turned on.

In addition, as described above, when the first HEMT is turned on, second gate structure 140 of the second HEMT may be the gate for controlling the switching of bidirectional switch 105, so that common drain region 135 can be used as the channel region for blocking a high voltage at first source structure 132 from reaching second source structure 142. Similarly, when the second HEMT is turned on, first gate structure 130 of the first HTMT may be the gate for controlling the switching of bidirectional switch 105, so that common drain region 135 can be used as the channel region for blocking a high voltage at second source structure 142 from reaching first source structure 132. In both cases, the common drain region 135 can have the high voltage. The distance between the gate structure and the corresponding source structure of each HEMT can be short as shown in FIG. 1B, while bidirectional switch 105 can still achieve high voltage blocking in both directions due to the sharing of common drain region 135. Since common drain region 135 is shared, the total channel length of bidirectional switch 105 can be much shorter than the total channel length of two separate HEMTs, and thus bidirectional switch 105 can have a reduced cell pitch (and thus a smaller device size) and a lower on-state resistance (Ron), while achieving high voltage blocking.

Since the two terminals of bidirectional switch 100 or 105 may be connected to the sources of two transistors and may be at different voltage levels before the bidirectional switch is turned on, different voltage levels may be applied to the gates of the two transistors in order to turn on the bidirectional switch. As such, each transistor in the bidirectional switch may be controlled by a driver that may be coupled to the gate of the transistor to provide the appropriate gate voltage. Each driver may have a driver input, a reference terminal (e.g., coupled to the source of a transistor of the bidirectional switch and thus a terminal of the bidirectional switch), a bias terminal (e.g., a power supply terminal), and a driver output coupled to a control terminal (e.g., a gate) of the transistor-based bidirectional switch. A bias circuit may be used to set an appropriate bias voltage level at the bias terminal of the driver so that the output of the driver can properly turn on or off a transistor of the bidirectional switch. Because the reference terminals of the two drivers are coupled to the two terminals of the bidirectional switch that may be at different voltage levels before the bidirectional switch is turned on, the bias terminals of the two drivers may be at different voltage levels so that the outputs of the two drivers can be at different levels to properly turn on or off the two transistors of the bidirectional switch. In some bidirectional switch control circuits, the bias circuit may include two voltage sources to apply different bias voltage levels to the bias terminals of the two drivers.

FIG. 2 is a schematic diagram of an example of a circuit 200 including a bidirectional switch 210 and circuits for controlling bidirectional switch 210. Bidirectional switch 210 may be formed by two transistors (e.g., HEMTs) with a common drain region 215. Bidirectional switch 210 may include a first terminal 212 (S1) that may be coupled to the source of a first transistor, and a second terminal 216 (S2) that may be coupled to the source of a second transistor. The first transistor may be controlled by a first driver 220 through a gate 214 (G1), and the second transistor may be controlled by a second driver 230 through a gate 218 (G2). First driver 220 may include a reference terminal 222, a bias terminal 224, an input terminal 226, and an output terminal 228. Reference terminal 222 may be coupled to first terminal 212 (S1) of bidirectional switch 210. Output terminal 228 may be coupled to gate 214 (G1). Second driver 230 may include a reference terminal 232, a bias terminal 234, an input terminal 236, and an output terminal 238. Reference terminal 232 may be coupled to second terminal 216 (S2) of bidirectional switch 210. Output terminal 238 may be coupled to gate 218 (G2).

When a voltage is applied between first terminal 212 (S1) and second terminal 216(S2) and bidirectional switch 210 is not turned on, first terminal 212 (S1) and second terminal 216(S2) may be at different voltage levels. To turn on bidirectional switch 210, gate 214 (G1) may have a voltage level that is greater than the voltage level of first terminal 212 (S1) by at least a threshold voltage of the first transistor, and gate 218 (G2) may have a voltage level that is greater than the voltage level of second terminal 216 (S2) by at least a threshold voltage of the second transistor. Since first terminal 212 (S1) and second terminal 216 (S2) (and thus reference terminal 222 and reference terminal 232) may be at different voltage levels, bias terminal 224 and bias terminal 234 may be at different levels as well so that the output voltage of first driver 220 and the output voltage of second driver 230 may be at different levels to turn on the first transistor and the second transistor. As shown in FIG. 2, a first isolated supply 225 may be used across reference terminal 222 and bias terminal 224 to apply a first bias voltage to bias terminal 224, and a second isolated supply 235 may be used across reference terminal 232 and bias terminal 234 to apply a second bias voltage to bias terminal 234. Due to the different voltage levels at reference terminals 222 and 232 and the different voltage levels at bias terminals 224 and 234, first isolated supply 225 or second isolated supply 235 may not be used for both first driver 220 and second driver 230.

According to some examples disclosed herein, the drivers for two control terminals of a bidirectional switch may receive respective bias voltages from a bias generator that generates the respective bias voltages using a single voltage supply. The bias generator may have a first input, a second input, a first bias output, and a second bias output. The first input may be coupled to a first switch terminal (e.g., the source of a first transistor) of the bidirectional switch (which may be coupled to the reference terminal of a first driver). The second input may be coupled to a second switch terminal (e.g., the source of a second transistor) of the bidirectional switch (which may be coupled to the reference terminal of a second driver). The first bias output may be coupled to the bias terminal of the first driver, and the second bias output may be coupled to the bias terminal of the second driver.

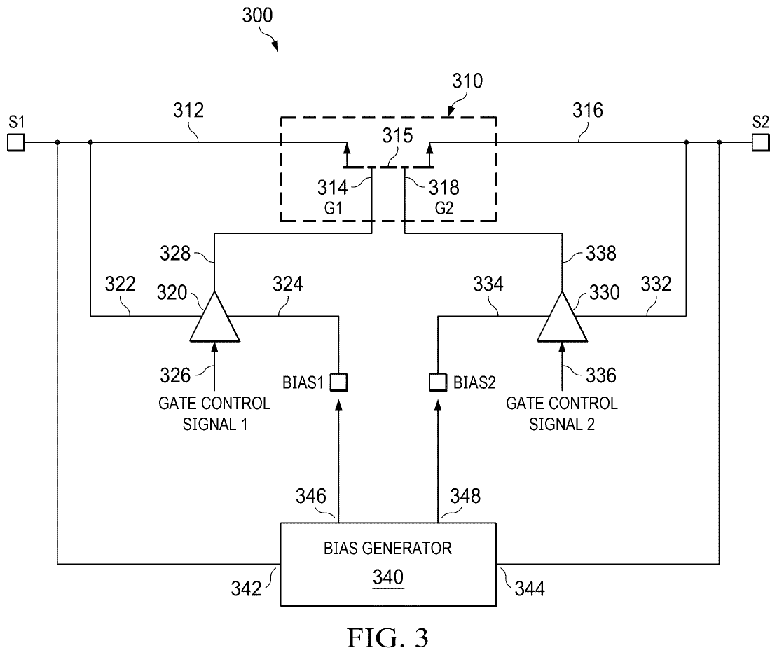

FIG. 3 is a block diagram of an example of a circuit 300 including a bidirectional switch 310 and circuits for controlling bidirectional switch 310. Bidirectional switch 310 may be formed by two transistors (e.g., HEMTs) with a common drain region 315. Bidirectional switch 310 may include a first terminal 312 (S1) that may be coupled to the source of a first transistor, and a second terminal 316 (S2) that may be coupled to the source of a second transistor. The first transistor has a gate 314 (G1) and may be controlled by a first driver 320, and the second transistor has a gate 318 (G2) and may be controlled by a second driver 330. First driver 320 may include a reference terminal 322, a bias terminal 324, an input terminal 326, and an output terminal 328. Reference terminal 322 may be coupled to first terminal 312 (S1) of bidirectional switch 310. Output terminal 328 may be coupled to gate 314 (G1). Second driver 330 may include a reference terminal 332, a bias terminal 334, an input terminal 336, and an output terminal 338. Reference terminal 332 may be coupled to second terminal 316 (S2) of bidirectional switch 310. Output terminal 338 may be coupled to gate 318 (G2).

A bias generator 340 can generate bias voltages for first driver 320 and second driver 330. Bias generator 340 may include a first input 342, a second input 344, a first bias output 346, and a second bias output 348. First input 342 may be coupled to reference terminal 322 of first driver 320 and first terminal 312 (S1) of bidirectional switch 310. Second input 344 may be coupled to second reference terminal 332 of second driver 330 and second terminal 316 (S2) of bidirectional switch 310. First bias output 346 may be coupled to bias terminal 324 of first driver 320. Second bias output 348 may be coupled to bias terminal 334. Bias generator 340 may generate, based on a single voltage supply, a first bias voltage at first bias output 346 and a second bias voltage at second bias output 348.

During a commutation transition where bidirectional switch 310 transitions from an off-state to an on-state where both transistors of bidirectional switch is turned on, bias generator 340 can provide the appropriate bias voltages for first driver 320 and second driver 330 to enable both drivers to provide sufficiently high voltages to turn on, respectively, the first and second transistors of bidirectional switch 310. In some examples, bias generator 340 may include a maximum voltage selector coupled to first input 342 and second input 344 and having an output, an isolated voltage source having a first (e.g., negative) supply terminal coupled to the output of the maximum voltage selector, a first bootstrap circuit coupled between a second (e.g., positive) supply terminal of the isolated voltage source and first bias output 346, and a second bootstrap circuit coupled between the second supply terminal and second bias output 348. In one example, the maximum voltage selector may include a third transistor and a fourth transistor that may have a common-drain terminal coupled to the output of the maximum voltage selector.

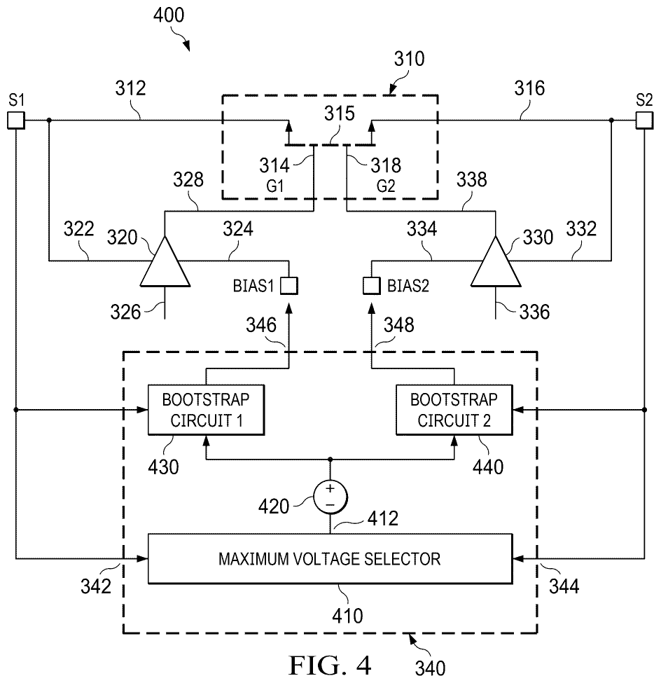

FIG. 4 is a block diagram of an example of a circuit 400 including bidirectional switch 310 and circuits for controlling bidirectional switch 310. Circuit 400 may be an example of circuit 300, and may include first driver 320 and second driver 330 as described above with respect to FIG. 3. In circuit 400, bias generator 340 may include a maximum voltage selector 410 that may select the higher voltage of the two voltages at first terminal 312 (S1) and second terminal 316(S2), and output the higher voltage at an output 412. Bias generator 340 may also include an isolated voltage source 420. In some examples, isolated voltage source 420 may be a galvanic isolated voltage supply. For example, isolated voltage source 420 may include a transformer that takes an alternative current (AC) supply voltage as input on one side (e.g., the primary side) of the transformer and a voltage rectification circuit on another side (e.g., the secondary side) of the transformer to generate a direct current (DC) voltage, where a terminal of the secondary side (e.g., the negative terminal of isolated voltage source 420) may be coupled to output 412 of maximum voltage selector 410, such that another terminal (e.g., the positive terminal) of isolated voltage source 420 may be at a voltage level that is the sum of the voltage level at output 412 of maximum voltage selector 410 and the DC voltage on the secondary side of the transformer. A first bootstrap circuit 430 and a second bootstrap circuit 440 may be coupled to the positive terminal of isolated voltage source 420.

First bootstrap circuit 430 has an input coupled to first terminal 312 (S1) and has a first bias output 346 coupled to bias terminal 324 of first driver 320. First bootstrap circuit 430 can generate a first bias voltage at first bias output 346 by bootstrapping the voltage at the first terminal 312 (e.g., by adding a voltage offset to the voltage). This allows the first bias voltage to track the voltage at first terminal 312, which in turn allows first driver 320, which receives the first bias voltage, to provide a driver voltage at output terminal 328 that tracks (and exceeds) the voltage at first terminal 312. Such a driver voltage allows the voltage difference between gate 314 and source S1 (first terminal 312) to exceed the threshold of the first transistor (of bidirectional switch 310) having gate 314 to fully turn on the first transistor, such as when the voltage at first terminal 312 (S1) rises from a low voltage to a high voltage due to bidirectional switch 310 being turned on and connect between first terminal 312 and second terminal 316 (S2), which has the high voltage.

Also, second bootstrap circuit 440 has an input coupled to second terminal 316 (S2) and has a second bias output 348 coupled to bias terminal 334 of second driver 330. Second bootstrap circuit 440 can generate a second bias voltage at second bias output 348 by bootstrapping (e.g., adding a voltage offset to) the voltage at the second terminal 316. This allows the second bias voltage to track the voltage at second terminal 316, which in turn allows second driver 330, which receives the second bias voltage, to also provide a driver voltage at output terminal 338 that tracks (and exceeds by an offset) the voltage at second terminal 316. Such a driver voltage allows the voltage difference between gate 318 and source S2 (second terminal 316) to exceed the threshold of the second transistor (of bidirectional switch 310) having gate 318 to fully turn on the second transistor, such as when the voltage at second terminal 316 (S2) rises from a low voltage to a high voltage due to bidirectional switch 310 being turned on and connect between second terminal 316 and first terminal 312, which has the high voltage.

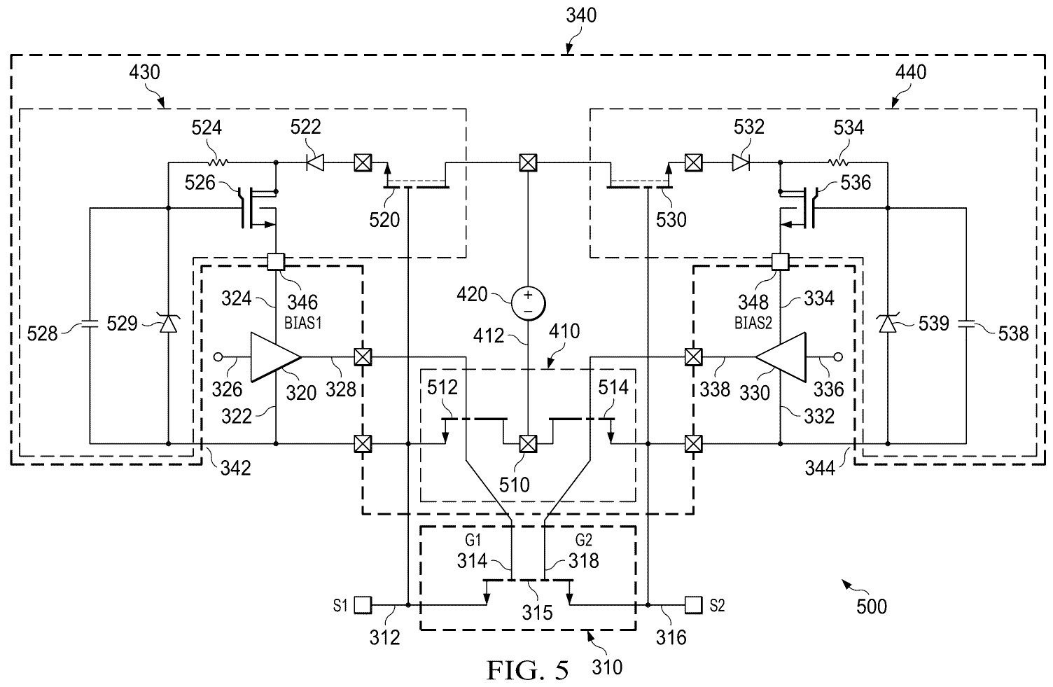

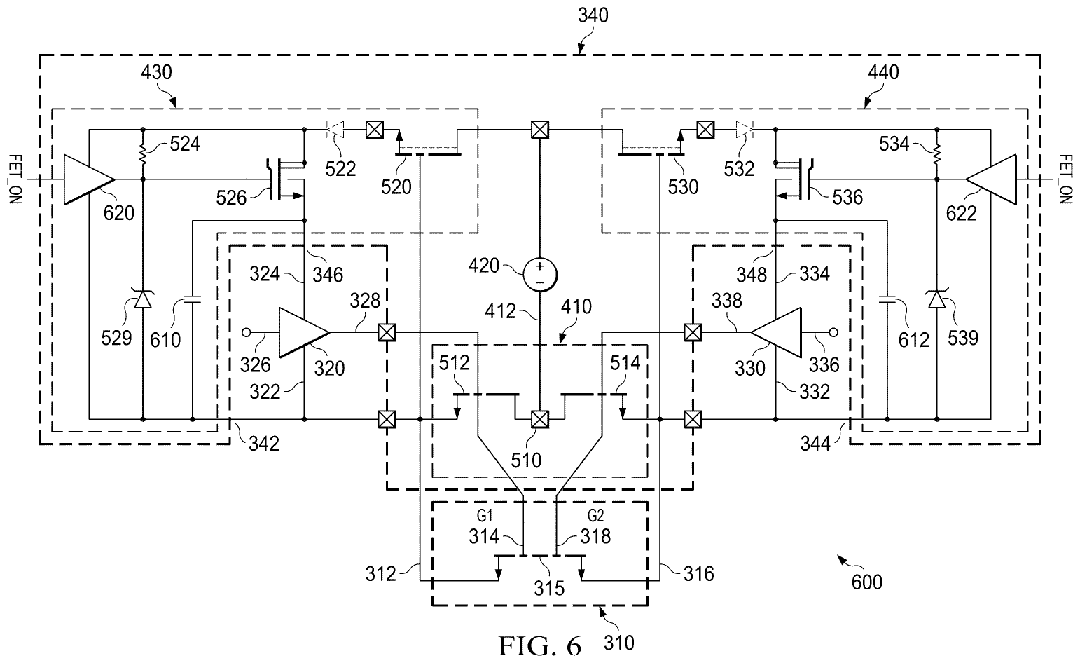

Further, as described above, both first bootstrap circuit 430 and second bootstrap circuit 440 may be coupled to the positive terminal of isolated voltage source 420. Accordingly, both first bootstrap circuit 430 and second bootstrap circuit 440 can receive a voltage that exceeds a maximum voltage between the voltage at sources S1 (first terminal 312) and S2 (second terminal 316). Such arrangements can ensure that charge can flow from voltage source 420 to first driver 320 via first bootstrap circuit 430 as first driver 320 brings up the voltage at gate 314 (via output terminal 328) to turn on the first transistor of bidirectional switch 310, such as when the voltage at source S1 rises. Such arrangements can also ensure that charge can flow from voltage source 420 to second driver 330 via second bootstrap circuit 440 as second driver 330 brings up the voltage at gate 318 (via output terminal 338) to turn on the second transistor of bidirectional switch 310, such as when the voltage at source S2 rises. More details of maximum voltage selector 410, first bootstrap circuit 430, and second bootstrap circuit 440 are described below with respect to FIGS. 5 and 6.

FIG. 5 is a schematic diagram of an example of a circuit 500 including bidirectional switch 310 and circuits for controlling the bidirectional switch. Circuit 500 may be an example of circuit 400, and may include first driver 320, second driver 330, and bias generator 340 described above with respect to FIGS. 3 and 4. Bias generator 340 may include maximum voltage selector 410, isolated voltage source 420, first bootstrap circuit 430, and second bootstrap circuit 440 as described above with respect to FIG. 4.

In the illustrated example, maximum voltage selector 410 may include a transistor 512 and a transistor 514 that share a common drain terminal 510, which may be output 412 of maximum voltage selector 410. Transistor 512 and transistor 514 may form an auxiliary common-drain bidirectional switch having a first terminal (e.g., at the source of transistor 512) and a second terminal (e.g., at the source of transistor 514). The first terminal and second terminal of the auxiliary common-drain bidirectional switch formed by transistor 512 and transistor 514 may be coupled to first terminal 312 (S1) and second terminal 316 (S2) of bidirectional switch 310, respectively. The gate of transistor 512 and the gate of transistor 514 may be coupled to gate 314 (G1) and gate 318 (G2), respectively. Therefore, the voltage level at common drain terminal 510 may be similar to the voltage level at common drain region 315 (which may not be accessible).

In one example operation, first terminal 312 (S1) is at a higher voltage level than second terminal 316 (S2), and the source of transistor 512 (coupled to S1) can also be at a higher voltage level than the source of transistor 514 (coupled to S2). Both the first and second transistors of bidirectional switch 310 and transistors 512 and 514 can be initially off with the gate and source of each of these transistors driven to the same voltage. Thus the voltage level at common drain terminal 510 may be similar to (e.g., with one threshold voltage drop) the voltage level at first terminal 312 (S1). Also, in another example operation, first terminal 312 (S1) is at a lower voltage level than second terminal 316 (S2), the source of transistor 512 may be at a lower voltage level than the source of transistor 514, and thus the voltage level at common drain terminal 510 may be similar to (e.g., with one threshold voltage drop) the voltage level at second terminal 316 (S2). Therefore, the voltage level at common drain terminal 510 may track the higher one of the voltage levels at first terminal 312 (S1) and second terminal 316 (S2). As illustrated, common drain terminal 510 may be coupled to the negative terminal of isolated voltage source 420.

In the illustrated example, the positive terminal of isolated voltage source 420 may be coupled to the drain of a depletion-mode transistor 520 of first bootstrap circuit 430 and to the drain of a depletion-mode transistor 530 of second bootstrap circuit 440. Depletion-mode transistor 520 may have a gate terminal coupled to first terminal 312 of bidirectional switch 310. When the voltage difference between the gate terminal and the source terminal of depletion-mode transistor 520 is greater than a threshold (e.g., a negative value, such as −20 V), depletion-mode transistor 520 may be in an ON state, such that the voltage level at the source of depletion-mode transistor 520 may be pulled up by the positive terminal of isolated voltage source 420. When the voltage level at the source of depletion-mode transistor 520 reaches a value such that the voltage difference between the gate terminal and the source terminal of depletion-mode transistor 520 is at or below the threshold (e.g., ≤−20 V), depletion-mode transistor 520 may be turned off. Thus, the source of depletion-mode transistor 520 may be pulled up to a voltage level that is about the threshold (e.g., 20 V) higher than the voltage level at first terminal 312 by transistor 520, and the voltage level at the source of depletion-mode transistor 520 tracks (and exceeds) the voltage level at first terminal 312. For example, if the voltage level at first terminal 312 is 0V, the source of transistor 520 can be pulled up to 20V. Also, if the voltage level at first terminal 312 is 600V, the source of transistor 520 can be pulled up to about 620v. Also, depletion-mode transistor 530 may function in the same manner as depletion-mode transistor 520, and thus the source of depletion-mode transistor 530 may be pulled up to a voltage level that is about the threshold (e.g., 20 V) higher than the voltage level at second terminal 316 by transistor 530.

In some examples, first bootstrap circuit 430 may also include a diode 522 and a voltage regulator that may include a source follower 526. Diode 522 may allow current to flow from depletion-mode transistor 520 to source follower 526, but may block current in the opposite direction. Source follower 526 may include a transistor with a resistor 524 coupled to the drain and gate terminals of the transistor. The source of the transistor may be coupled to the first bias output 346 of bias generator 340, which may be coupled to the bias terminal of first driver 320. The voltage regulator of first bootstrap circuit 430 may also include a capacitor 528 and a Zener diode 529 coupled to the gate of the transistor of source follower 526. Capacitor 528 may function as a filter capacitor to reduce the high-frequency output impedance of source follower 526. A current can flow from transistor 520 through resistor 524 into Zener diode 529, which can clamp the voltage difference between the gate of source follower 526 and reference terminal 322 of first driver 320 at the forward voltage of the Zener diode (e.g., 5V) responsive to the current. Source follower 526 can provide a voltage at first bias output 346/bias terminal 324) with reference to the voltage at reference terminal 322 based on the voltage difference (with one threshold voltage drop), and clamp/regulate the voltage at a value based on the voltage difference.

In some examples, second bootstrap circuit 440 may include a diode 532 and a source follower 536. Diode 532 may allow current to flow from depletion-mode transistor 530 to source follower 536, but may block current in the opposite direction. Source follower 536 may include a transistor with a resistor 534 coupled to the drain and gate terminals of the transistor. The source of the transistor of source follower 536 may be coupled to second bias output 348 of bias generator 340, which may be coupled to the bias terminal of second driver 330. Second bootstrap circuit 440 may also include a capacitor 538 and a Zener diode 539 coupled to the gate of the transistor of source follower 536. Capacitor 538 may function as a filter capacitor to reduce the high-frequency output impedance of source follower 536. A current can flow from transistor 530 through resistor 534 into Zener diode 539, which can clamp the voltage difference between the gate of source follower 536 and reference terminal 332 of second driver 330 at the forward voltage of the Zener diode (e.g., 5V) responsive to the current. Source follower 536 can provide a voltage at second bias output 334/bias terminal 348 with reference to the voltage at reference terminal 322 based on the voltage difference (with one threshold voltage drop), and clamp/regulate the voltage at a value based on the voltage difference.

When second terminal 316 (S2) of bidirectional switch 310 is at a voltage level (e.g., a few hundred volts such as 600 V) higher than the voltage level (e.g., 0 V) of first terminal 312 (S1) before bidirectional switch 310 is enabled, the voltage level at output 412 of maximum voltage selector 410 (e.g., at common drain terminal 510) may be close to the voltage level at second terminal 316 (S2), such as about 600 V minus a threshold voltage of the second transistor. The positive terminal of isolated voltage source 420 may be at a voltage level that is higher than the voltage level at common drain terminal 510 by a supply voltage of isolated voltage source 420. In a case where the isolated voltage source 420 provides a 20 V difference, the positive terminal of isolated voltage source can be at 620 V. Depletion-mode transistors 520 and 530 may both be in an ON state initially, such that the sources of depletion-mode transistors 520 and 530 may be pulled up by the voltage level at the positive terminal of isolated voltage source 420. The current for pulling up the source of depletion-mode transistors 520 may flow, for example, from second terminal 316 through transistor 514, isolated voltage source 420, depletion-mode transistor 520, source follower 526, first driver 320, and gate of transistor 512, to a load at first terminal 312 of bidirectional switch 310.

Depletion-mode transistor 520 may be turned off when the voltage level at the source of depletion-mode transistors 520 reaches a level (e.g., about 20 V, as explained above) such that the voltage difference between the gate (e.g., at about 0 V) and the source of depletion-mode transistor 520 is equal to the negative threshold voltage of depletion-mode transistor 520. The voltage level (e.g., up to about 20 V) at the source of depletion-mode transistor 520 may be applied to bias terminal 324 through diode 522 and source follower 526, which may reduce the voltage level such that first driver 320 may be properly biased (e.g., at about 5 V above the voltage at reference terminal 322) at bias terminal 324 to generate an output that can turn on the first transistor of bidirectional switch 310, when input terminal 326 of first driver 320 is controlled to turn on the first transistor of bidirectional switch 310. Due to a voltage difference between the drain and source of depletion-mode transistor 520 and the current passing through depletion-mode transistor 520, there may be power loss on depletion-mode transistor 520 before the first transistor of bidirectional switch 310 and transistor 512 are turned on. After the first transistor of bidirectional switch 310 is turned on (e.g., when the V_{GS} of the first transistor is higher than the Miller plateau), the voltage level at first terminal 312 may be similar to the voltage level at second terminal 316 (e.g., about 600 V), and the voltage drop between the drain and source of depletion-mode transistor 520 may be low (and thus the power loss at depletion-mode transistor 520 may be low).

Similarly, depletion-mode transistor 530 may be turned off when the voltage level at the source of depletion-mode transistors 530 reaches a level (e.g., about 620 V, as explained above) such that the voltage difference between the gate (e.g., at about 600 V) and the source of depletion-mode transistor 530 is lower than the negative threshold voltage (e.g., about −20 V) of depletion-mode transistor 530. The voltage level (e.g., about 620 V) at the source of depletion-mode transistor 530 may be applied to bias terminal 334 through diode 532 and source follower 536, which may reduce the voltage level such that second driver 330 (e.g., having 600 V at reference terminal 332) may be properly biased (e.g., at about 605 V) at bias terminal 334 to generate an output that can turn on the second transistor of bidirectional switch 310, when input terminal 336 of second driver 330 is controlled to turn on the second transistor of bidirectional switch 310.

Due to its symmetrical structure, circuit 500 may function in a similar manner when first terminal 312 (S1) of bidirectional switch 310 is at a voltage level (e.g., a few hundred vols such as 600 V) higher than the voltage level (e.g., 0 V) of second terminal 316 (S2). Therefore, circuit 500 may provide bidirectional voltage blocking and switching.

FIG. 6 is a schematic diagram of an example of a circuit 600 including bidirectional switch 310 and circuits for controlling the bidirectional switch. Circuit 600 may be another example of circuit 400, and may include first driver 320, second driver 330, and bias generator 340 described above with respect to FIGS. 3 and 4. In the illustrated example, bias generator 340 may include maximum voltage selector 410, isolated voltage source 420, and bootstrap circuits 430 and 440. For example, as described above with respect to FIG. 4, bias generator 340 in circuit 600 may include bootstrap circuit 430 that may include depletion-mode transistor 520, diode 522, and a voltage regulator (e.g., including source follower 526). Bias generator 340 may also include bootstrap circuit 440 that may include depletion-mode transistor 530, diode 532, and a voltage regulator (e.g., including source follower 536). In the example shown in FIG. 6, diodes 522 and 532 may be omitted. Resistor 524 may be coupled to the drain and gate terminals of source follower 526. The source of source follower 526 may be coupled to first bias output 346 of bias generator 340, which may be coupled to the bias terminal of first driver 320. Zener diode 529 can regulate the voltage difference between bias terminal 324 and reference terminal 322 of first driver 320, such that the voltage difference between bias terminal 324 and reference terminal 322 of first driver 320 may not exceed the breakdown voltage of Zener diode 529. Similarly, resistor 534 may be coupled to the drain and gate terminals of source follower 536. The source of source follower 536 may be coupled to second bias output 348 of bias generator 340, which may be coupled to the bias terminal of second driver 330. Zener diode 529 can regulate the voltage difference between bias terminal 334 and reference terminal 332 of second driver 330, such that the voltage difference between bias terminal 334 and reference terminal 332 of second driver 330 may not exceed the breakdown voltage of Zener diode 539.

In the example illustrated in FIG. 6, bias generator 340 may also include capacitors 610 and 612 and drivers 620 and 622. Capacitors 610 and 612 may be bootstrap capacitors that can provide bias voltages to first driver 320 and second driver 330. Drivers 620 and 622 may control the gates of source followers 526 and 536, respectively, and can turn off source follower 526 or 536 before bidirectional switch 310 is turned on, such that no charge may flow from depletion-mode transistor 520 or 530 before bidirectional switch 310 is fully turned on (e.g., with the V_{GS} of the two transistors greater than the Miller plateau), thereby avoiding power loss caused by the current passing through depletion-mode transistor 520 or 530 and the large voltage drop on depletion-mode transistor 520 or 530 before bidirectional switch 310 is turned on. Prior to source follower 526/536 being turned on, capacitors 610 and 612 can discharge to provide the charge to, respectively, first driver 320 and second driver 330 to enable them to provide the voltages to turn on bidirectional switch 310.

After bidirectional switch 310 is turned on (e.g., with the V_{GS} of the two transistors greater than the Miller plateau), first terminal 312 and second terminal 316 may have the same or similar voltage level, and source followers 526 and 536 may be turned on. When source followers 526 and 536 are turned on, depletion-mode transistor 520, diode 522 (which can be optional in FIG. 6), and the voltage regulator (including source follower 526) of the first bootstrap circuit, and depletion-mode transistor 530, diode 532 (which can be optional in FIG. 6), and the voltage regulator (including source follower 536) of the second bootstrap circuit may function as described above with respect to FIG. 5 to generate two bias voltages at first bias output 346 and second bias output 348, such that capacitors 610 and 612 may be charged to restore charges lost while source followers 526 and 536 and bidirectional switch 310 are turned off.

For example, after bidirectional switch 310 is turned on, common drain terminal 510, first terminal 312, second terminal 316, the gate of depletion-mode transistor 520, and the gate of depletion-mode transistor 530 may all be at a high voltage level (e.g., about 600 V), while the drains of depletion-mode transistor 520 and depletion-mode transistor 530 may both be at a voltage level that is higher than the voltage level at common drain terminal 510 by the supply voltage of isolated voltage source 420. Thus, the voltage levels at the sources of depletion-mode transistor 520 and depletion-mode transistor 530 may be higher than the voltage levels of the gates of depletion-mode transistors 520 and 530 by up to a threshold voltage (e.g., about 20 V) of the depletion-mode transistors. Therefore, the voltage drop between the drain and source of depletion-mode transistor 520 may be low (e.g., close to 0 V), and the voltage drop between the drain and source of depletion-mode transistor 530 may be low (e.g., close to 0 V). The voltage difference (e.g., up to about 20 V) between the source and gate of depletion-mode transistor 520 may be regulated by the voltage regulator in the first bootstrap circuit to provide the first bias voltage (e.g., about 5 V higher than the voltage level at first terminal 312) to charge capacitor 610. Similarly, the voltage difference (e.g., up to about 20 V) between the source and gate of depletion-mode transistor 530 may be regulated by the voltage regulator in the second bootstrap circuit to provide the second bias voltage (e.g., about 5 V higher than the voltage level at second terminal 316) to charge capacitor 612. Due to the low voltage drop on the current path (e.g., on depletion-mode transistors 520 and 530) for restoring charges on capacitors 610 and 612, the power loss of bias generator 340 can be reduced.

In some examples, bias generator 340 may include a minimum voltage selector coupled to first input 342 and second input 344 and having an output. The bias generator may also include an isolated voltage source having a first (e.g., negative) supply terminal coupled to the output of the minimum voltage selector, a first bootstrap circuit coupled between a second (e.g., positive) supply terminal of the isolated voltage source and first bias output 346, and a second bootstrap circuit coupled between the second supply terminal of the isolated voltage source and second bias output 348. In one example, the minimum voltage selector may include a first switch between the first input 342 and the output of the minimum voltage selector, and a second switch between the second input 344 and the output of the minimum voltage selector.

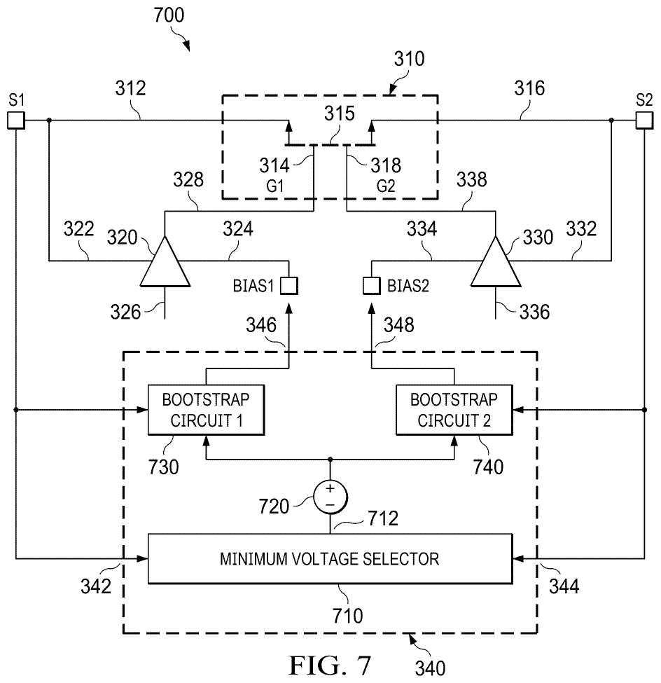

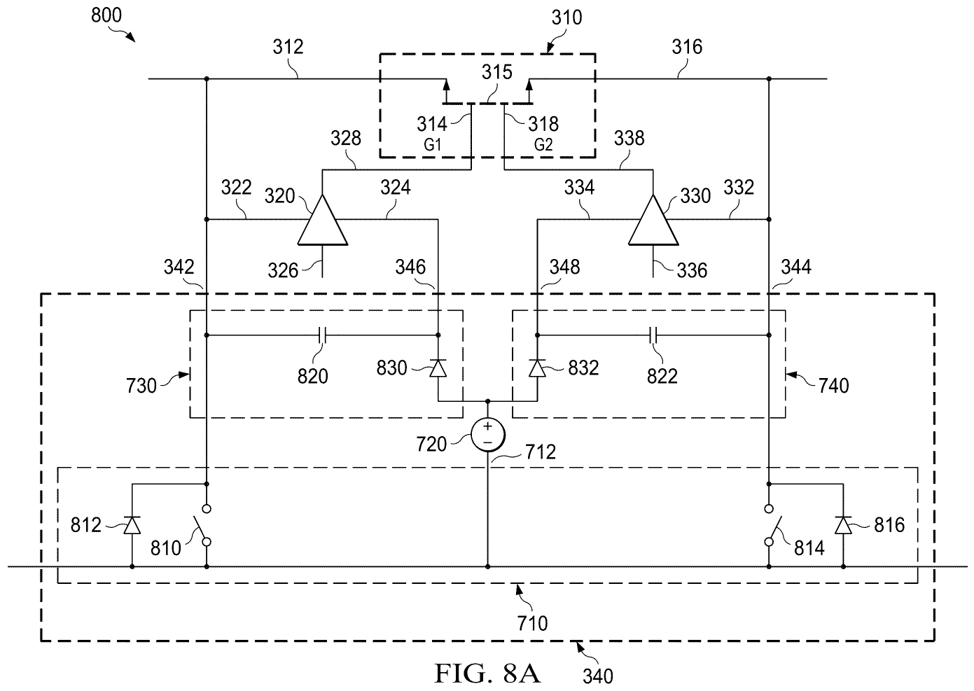

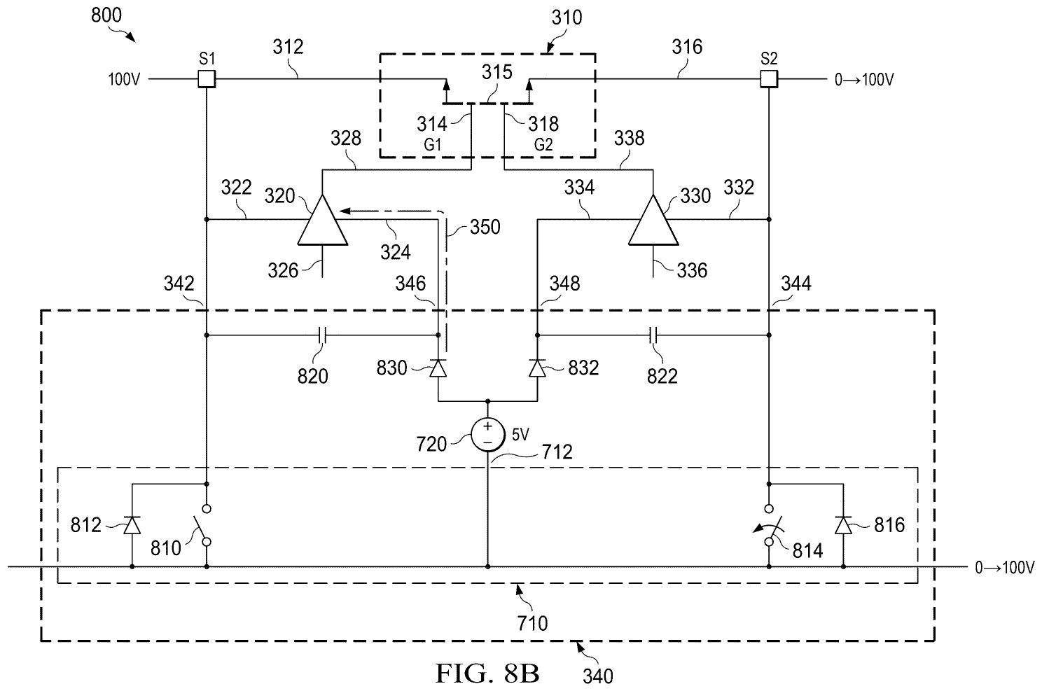

FIG. 7 is a block diagram of an example of a circuit 700 including bidirectional switch 310 and circuits for controlling the bidirectional switch. Circuit 700 may be an example of circuit 300, and may include first driver 320 and second driver 330 as described above with respect to FIG. 3. In circuit 700, bias generator 340 may include a minimum voltage selector 710 that may select the lower voltage of the two voltages at first terminal 312 (S1) and second terminal 316 (S2) and output the lower voltage at an output 712. Bias generator 340 may also include an isolated voltage source 720, which may be similar to isolated voltage source 420 described above. Voltage source 720 provides a voltage at the positive terminal by adding a voltage offset to the voltage output by minimum voltage selector 710. A first bootstrap circuit 730 and a second bootstrap circuit 740 may be coupled to the positive terminal of isolated voltage source 720 to generate a first bias voltage at first bias output 346 that is coupled to bias terminal 324 of first driver 320, and a second bias voltage at second bias output 348 that is coupled to bias terminal 334 of second driver 330. The first and second bias voltages can be generated by bootstrapping relative to the voltage at the positive terminal of voltage source 720. Examples of minimum voltage selector 710, first bootstrap circuit 730, and second bootstrap circuit 740 are described below with respect to FIGS. 8A and 8B.

FIG. 8A is a schematic diagram of an example of a circuit 800 including bidirectional switch 310 and circuits for controlling bidirectional switch 310. Circuit 800 may be an example of circuit 700, and may include first driver 320, second driver 330, and bias generator 340 described above with respect to FIGS. 3 and 7. Bias generator 340 in circuit 800 may include minimum voltage selector 710, isolated voltage source 720, first bootstrap circuit 730, and second bootstrap circuit 740 as described above with respect to FIG. 7.

Minimum voltage selector 710 may have a first input (at first input 342 of bias generator 340), a second input (at second input 344 of bias generator 340), and an output 712 as described above. As described above, first input 342 and second input 344 of bias generator 340 may be coupled to first terminal 312 and second terminal 316, respectively. First input 342 may be coupled to output 712 though a switch 810, while second input 344 may be coupled to output 712 though a switch 814. Optional diodes 812 and 816 can ensure that output 712 may be at the lower voltage of the two voltages at first terminal 312 (S1) and second terminal 316 (S2). Switches 810 and 814 can be controlled by a circuit (e.g., a voltage comparator not shown in the figures) that compares between the voltage levels at first terminal 312 (S1) and second terminal 316 (S2). Switch 810 may be closed when the voltage level at first terminal 312 (S1) is lower than the voltage level at second terminal 316(S2), while switch 814 may be closed when the voltage level at second terminal 316 (S2) is lower than the voltage level at first terminal 312 (S1).

First bootstrap circuit 730 may include a capacitor 820 coupled between reference terminal 322 and bias terminal 324 of first driver 320, and a diode 830 coupled between the positive terminal of isolated voltage source 720 and bias terminal 324. Second bootstrap circuit 740 may include a capacitor 822 coupled between reference terminal 332 and bias terminal 334 of second driver 330, and a diode 832 coupled between the positive terminal of isolated voltage source 720 and bias terminal 334. Capacitors 820 and 822 are bootstrap capacitors to provide a voltage difference between the respective bias terminals and reference terminals of first driver 320 and second driver 330. Diodes 830 and 832 are blocking diodes to prevent charge from flowing from the bootstrap capacitors 820/832 back to the positive terminal of voltage source 720 if the voltage at the positive terminal becomes lower than the bias terminals.

FIG. 8B illustrates an example of an operation of circuit 800 of FIG. 8A. In the example illustrated in FIG. 8B, first terminal 312 (S1) of bidirectional switch 310 may be at a higher level (e.g., several hundred volts such as about 100 V) than second terminal 316 (S2) (e.g., at about 0 V before bidirectional switch 310 is turned on). Bidirectional switch 310 is in the off-state, with gate 314 and source S1 (first terminal 312) having the same voltage to turn off the first transistor, and gate 318 and source S2 (second terminal 316) also having the same voltage turn off the second transistor. Also, switch 814 may be closed and switch 810 may be open to connect output 712 to second terminal 316, due to second terminal 316 having a lower voltage than first terminal 312, such that output 712 may be at about 0 V initially. Isolated voltage source 720 may have a supply voltage, for example, about 5V, and thus the positive terminal of isolated voltage source 720 may be at about 5V and the voltage levels at first bias output 346 and second bias output 348 may be close to 5 V (e.g., slightly lower than 5 V due to voltage drop on diodes 830 and 832). Therefore, bias terminal 334 of second driver 330 may be at a voltage level close to 5 V, and capacitor 822 may be charged to about 5 V. Since bias terminal 334 may be at about 5 V, and reference terminal 332 may be at 0 V, second driver 330 may be properly biased such that it may generate a voltage level at output terminal 338 and gate 318 to turn on the second transistor of bidirectional switch 310 when a proper input is received at second driver 330.

During a commutation transition, bidirectional switch 310 is to be turned on. Second driver 330 provides a voltage at output terminal 338 and gate 318 relative to reference terminal 332 high enough (e.g., 5V) to turn on the second transistor, which causes a current to flow from first terminal 312 to second terminal 316. The first transistor, having both gate 314 and source (S1) at 100V, conducts the current and discharge the common drain 315 to a voltage similar to 100 V (e.g., with one threshold voltage drop). The current can also charge up second terminal 316, so that the voltage level at second terminal 316 may rise from about 0 V to about 100 V, and thus the voltage level at output 712 may rise from about 0 V to about 100 V. As a result, the positive terminal of isolated voltage source 720 may be at about 105 V. Charge (represented by arrow 350 in FIG. 8B) can flow from the positive terminal of isolated voltage source 720 through diode 830 to bootstrap capacitor 820, and the voltage level at first bias output 346 may be close to about 105 V. Therefore, the voltage difference between bias terminal 324 (e.g., at about 105 V) and reference terminal 322 (at about 100 V) of first driver 320 may be about 5 V, and thus the first transistor of bidirectional switch 310 may be turned on by first driver 320. Meanwhile, bootstrap capacitor 822 can maintain the voltage difference between bias terminal 334 and reference terminal 334 of second driver 330, so that the voltage at second bias output 348 also increases (e.g., from 5V to 105V), and second driver 330 can also provide a sufficiently high voltage (relative to second terminal 316) to continue to turn on the second transistor of bidirectional switch 310. As such, both transistors of bidirectional switch 310 may be turned on and bidirectional switch 310 may have a low on-state resistance.

Due to its symmetrical structure, circuit 800 may function in a similar manner when second terminal 316 (S2) of bidirectional switch 310 is at a voltage level (e.g., a few hundred vols) higher than the voltage level (e.g., 0 V) of first terminal 312 (S2). Therefore, circuit 800 may provide bidirectional voltage blocking and switching.

In some examples, bias generator 340 may include a charge transfer circuit coupled between first and second bias outputs 346 and 348. In some examples, the charge transfer circuit may include an auxiliary bidirectional switch. The auxiliary bidirectional switch may be controlled by two auxiliary drivers that receive the same bias voltage and the same reference voltage as the first driver or the second driver. In one example, bias generator 340 may also include a first voltage source (e.g., a first bootstrap capacitor or isolated voltage supply) coupled between first input 342 and first bias output 346, a first startup circuit coupled between second bias output 348 and first input 342 and including a first output terminal coupled to the first bias output 346, a second voltage source (e.g., a second bootstrap capacitor or isolated voltage supply) coupled between second input 344 and second bias output 348, and a second startup circuit coupled between first bias output 346 and second input 344 and including a second output terminal coupled to second bias output 348. In another example, bias generator 340 may include a voltage supply including a positive terminal and a negative terminal coupled to first input 342, a first bootstrap capacitor coupled between first input 342 and first bias output 346, a first voltage regulator (e.g., including a source follower) coupled between the positive terminal of the voltage supply and first bias output 346, a second bootstrap capacitor coupled between second input 344 and second bias output 348, a second auxiliary bidirectional switch including a first terminal coupled to the positive terminal of the voltage supply, and a second voltage regulator (e.g., including a source follower) coupled between a second terminal of the second auxiliary bidirectional switch and second bias output 348.

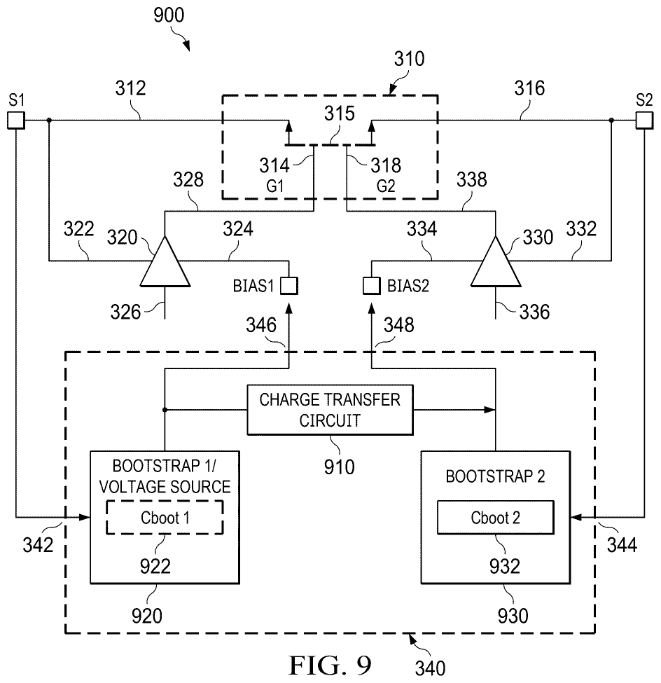

FIG. 9 is a block diagram of an example of a circuit 900 including bidirectional switch 310 and circuits for controlling bidirectional switch 310. Circuit 900 may be an example of circuit 300, and may include first driver 320 and second driver 330 as described above with respect to FIG. 3. In circuit 900, bias generator 340 may include a charge transfer circuit 910 (e.g., a spill-over circuit) coupled between first bias output 346 and second bias output 348. Bias generator 340 may also include a first bootstrap circuit 920 (or a voltage source) and a second bootstrap circuit 930 (or a voltage source). First bootstrap circuit 920 may include a bootstrap capacitor 922 (or a voltage source) and may be coupled between first input 342 and first bias output 346. Second bootstrap circuit 930 may include a bootstrap capacitor 932 (or a voltage source) and may be coupled between second input 344 and second bias output 348. One of the first bootstrap circuit 920 or second bootstrap circuit 930 may include or may be coupled to a power supply (e.g., an isolated voltage source) to charge up the respective bootstrap capacitor 922/932. During operation, charge may be transferred from one of the bootstrap circuit that includes or is coupled to a power supply to the other bootstrap circuit that does not include (or is not coupled to) a power supply, to equalize the voltage at first bias output 346 and second bias output 348.

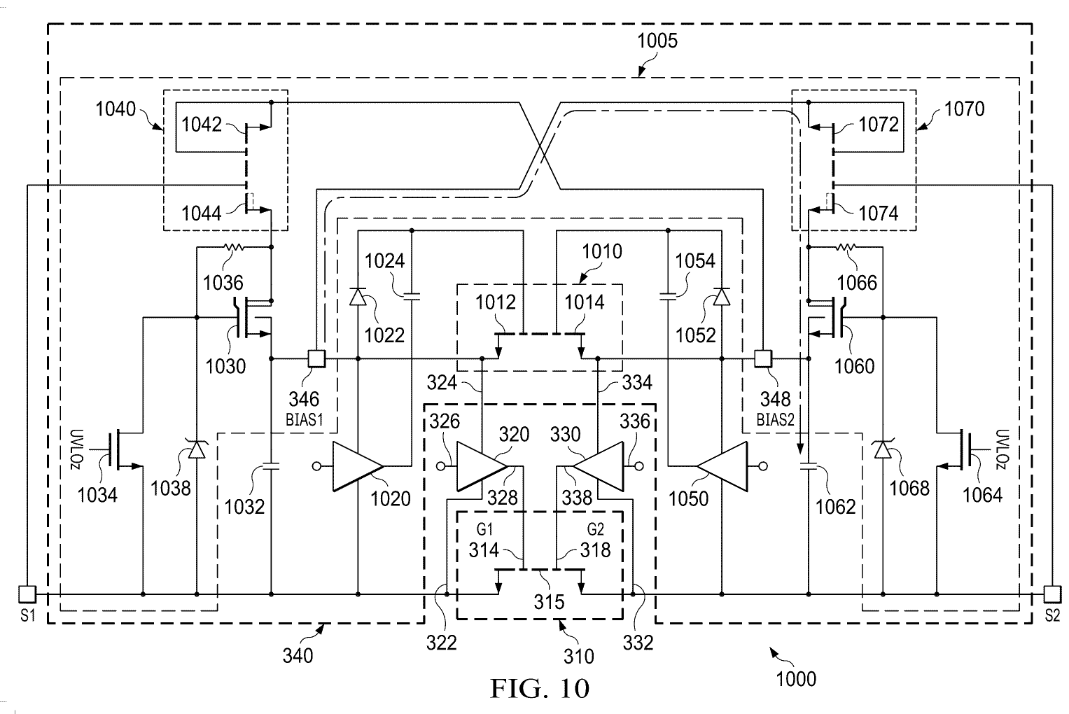

FIG. 10 is a schematic diagram of an example of a circuit 1000 including bidirectional switch 310 and circuits for controlling bidirectional switch 310. Circuit 1000 may be an example of circuit 900, and may include first driver 320 and second driver 330 as described above with respect to FIGS. 3 and 9. In circuit 1000, bias generator 340 may include a charge transfer circuit that includes an auxiliary bidirectional switch 1010 and the corresponding control circuits, such as auxiliary drivers 1020 and 1050 used to drive the dual gates of auxiliary bidirectional switch 1010. The charge transfer circuit can transfer charges from a voltage source (e.g., an isolated voltage supply) on one side of auxiliary bidirectional switch 1010 to a voltage source (e.g., a bootstrap capacitor) on the other side of auxiliary bidirectional switch 1010.

In the illustrated example, bias generator 340 may include a first voltage source 1032 (represented by a capacitor in FIG. 10) coupled between bias terminal 324 and reference terminal 322 of first driver 320, and a second voltage source 1062 (represented by another capacitor in FIG. 10) coupled between bias terminal 334 and reference terminal 332 of second driver 330. First voltage source 1032 can correspond to (or can be part of) first bootstrap circuit 920, and second voltage source 1062 can correspond to (or can be part of) second bootstrap circuit 930. First voltage source 1032 may also be coupled between a bias terminal and a reference terminal of auxiliary driver 1020, while second voltage source 1062 may also be coupled between a bias terminal and a reference terminal of auxiliary driver 1050. One terminal (e.g., the positive terminal) of first voltage source 1032 may be coupled to first bias output 346 of bias generator 340. One terminal (e.g., the positive terminal) of second voltage source 1062 may be coupled to second bias output 348 of bias generator 340. One of first voltage source 1032 and second voltage source 1062 may be a voltage supply, such as an isolated voltage supply similar to isolated voltage source 420 or 720 described above. The other one of first voltage source 1032 and second voltage source 1062 may be a bootstrap capacitor. First voltage source 1032 and second voltage source 1062 can bias first driver 320 and second driver 330 so that first driver 320 and second driver 330 may drive the dual gates of bidirectional switch 310 to turn on the two transistors of bidirectional switch 310 during normal operations. For illustration purposes, circuit 1000 may be described using an example where first voltage source 1032 may be a voltage supply and second voltage source 1062 may be a bootstrap capacitor. In another example, second voltage source 1062 may be a voltage supply and first voltage source 1032 may be a bootstrap capacitor. In both cases, the voltage source/capacitor sets a voltage difference between the bias terminal and the reference terminal of the driver.

Auxiliary bidirectional switch 1010 may be a common-drain bidirectional switch that is similar to bidirectional switch 310 or may include two transistors with their drain terminals connected together. For example, auxiliary bidirectional switch 1010 may include a transistor 1012 and a transistor 1014. As described above, transistors 1012 and 1014 may be HEMTs, such as GaN-based HEMTs. The source of transistor 1012 may be coupled to first bias output 346 and the positive terminal of first voltage source 1032 (e.g., a voltage supply), while the source of transistor 1014 may be coupled to second bias output 348 and the positive terminal of second voltage source 1062 (e.g., a bootstrap capacitor). The gate of transistor 1012 may be driven by the output of auxiliary driver 1020 through a charge pump capacitor 1024, and the gate of transistor 1014 may be driven by the output of auxiliary driver 1050 through a charge pump capacitor 1054. Charge pump capacitors 1024 and 1054 may provide gate drive voltages that may be higher than the outputs of auxiliary drivers 1020 and 1050 and the sources of transistors 1012 and 1014. The charge transfer circuit may also include a diode 1022 coupled between the gate and source of transistor 1012, and a diode 1052 coupled between the gate and source of transistor 1014. Diodes 1022 and 1052 can bring up the voltage level at the gate of transistor 1012 or 1014 when the output of auxiliary driver 1020 or 1050 is at a low voltage level. After bidirectional switch 310 is turned on by drivers 320 and 330 that are biased by first voltage source 1032 and second voltage source 1062, auxiliary bidirectional switch 1010 may also be turned on by auxiliary drivers 1020 and 1050 that are also biased by first voltage source 1032 and second voltage source 1062, such that charge may be transferred from first voltage source 1032 (e.g., a voltage supply) to the capacitor of second voltage source 1062 through auxiliary bidirectional switch 1010 (which may have a low on-state resistance and a low voltage drop) to replenish the capacitor of second voltage source 1062 so that second driver 330 may be properly biased.

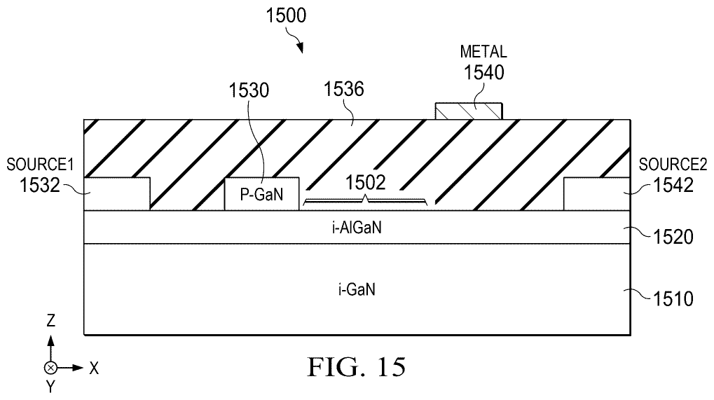

Bias generator 340 may also include a startup circuit 1005 that can properly bias the drivers of bidirectional switch 310 and auxiliary bidirectional switch 1010 in the event the bootstrap capacitor on the other side of auxiliary bidirectional switch 1010 has a low voltage at startup. As shown, startup circuit 1005 may include a bidirectional switch 1040 and a first voltage regulator on one side (which may be optional when first voltage source 1032 includes a voltage supply), and a bidirectional switch 1070 and a second voltage regulator on another side (which may be optional when second voltage source 1062 includes a voltage supply). The first voltage regulator may include a source follower that may include a transistor 1030 and a resistor 1036 coupled between the drain and gate of transistor 1030, a Zener diode 1038 coupled to the gate of transistor 1030, and a switch 1034 that may control the gate of transistor 1030. The source of transistor 1030 of the source follower may be coupled to first bias output 346. Bidirectional switch 1040 may include an E-mode transistor 1042 and a D-mode transistor 1044 sharing a common drain or with their drains coupled together. An example of bidirectional switch 1040 is shown in FIGS. 15A and 15B. The second voltage regulator may include a source follower that may include a transistor 1060 and a resistor 1066 coupled between the drain and gate of transistor 1060, a Zener diode 1068 coupled to the gate of transistor 1060, and a switch 1064 that may control the gate of transistor 1060. The source of transistor 1060 may be coupled to second bias output 348. Bidirectional switch 1070 may include an E-mode transistor 1072 and a D-mode transistor 1074 sharing a common drain or with their drains coupled together. In some examples, the first and second voltage regulators can be part of, respectively, bootstrap circuits 920 and 930.

Startup circuit 1005 can properly bias the drivers of bidirectional switch 310 in the event the bootstrap capacitor on one side of bidirectional switch 310 has a low voltage level at the startup of bidirectional switch 310. For example, when first voltage source 1032 includes a voltage supply, first driver 320 may be properly biased and may be able to turn on the first transistor of bidirectional switch 310, but second voltage source 1062 (e.g., a capacitor) may be at a low voltage level such that second driver 330 may not be properly biased and thus may not be able to turn on the second transistor of bidirectional switch 310 at the startup. In one example, bidirectional switch 1070 and the second voltage regulator of startup circuit 1005 can charge the capacitor of second voltage source 1062 so that second driver 330 may be properly biased. For example, when the voltage level of second voltage source 1062 is low, D-mode transistor 1074 may be in the ON state because the voltage difference (e.g., a negative value) between the gate and source of D-mode transistor 1074 is greater than the negative threshold voltage (e.g., about −20 V). The gate and source of E-mode transistor 1072 may be at a voltage level that is the sum of the supply voltage of first voltage source 1032 and the voltage level of first terminal 312, which may be high initially or may reach a high level when the second transistor of bidirectional switch 310, with gate and source at the same voltage, operates similarly to a forward-biased diode and conducts a current that flows through first transistor of bidirectional switch 310, which is turned on by first driver 320. Thus, the source of D-mode transistor 1074 may be at a level close to the voltage level at first voltage source 1032 and first bias output 346. Switch 1064 may be turned off when the voltage level of second voltage source 1062 is low, so that transistor 1060 of the source follower of the second voltage regulator may be turned on. Therefore, a current may flow from first voltage source 1032 through bidirectional switch 1070 and the second voltage regulator to the capacitor of second voltage source 1062 to charge the capacitor, as shown in FIG. 10, such that second driver 330 may be properly biased to turn on the second transistor of bidirectional switch 310.

After the capacitor of second voltage source 1062 is at a high level and bidirectional switch 310 is turned on, the voltage levels at first terminal 312 and second terminal 316 of bidirectional switch 310 may be similar, auxiliary bidirectional switch 1010 may be turned on for charge transfer (which may be referred to as spill-over), and switch 1064 may be turned on to bring the voltage level at the gate of transistor 1060 down and turn off the source follower. Therefore, charges may not be transferred between first voltage source 1032 and second voltage source 1062 through a path including bidirectional switch 1070 and the second voltage regulator, which may have a larger voltage drop and a higher power loss. But charges may be transferred between first voltage source 1032 and second voltage source 1062 through auxiliary bidirectional switch 1010 that may have a low voltage drop and thus a low power loss, to replenish the capacitor of second voltage source 1062.

If second voltage source 1062 includes a voltage supply and first voltage source 1032 is a capacitor, bidirectional switch 1040 and the first voltage regulator in startup circuit 1005 may be used in a similar manner as described above with respect to bidirectional switch 1070 and the second voltage regulator.

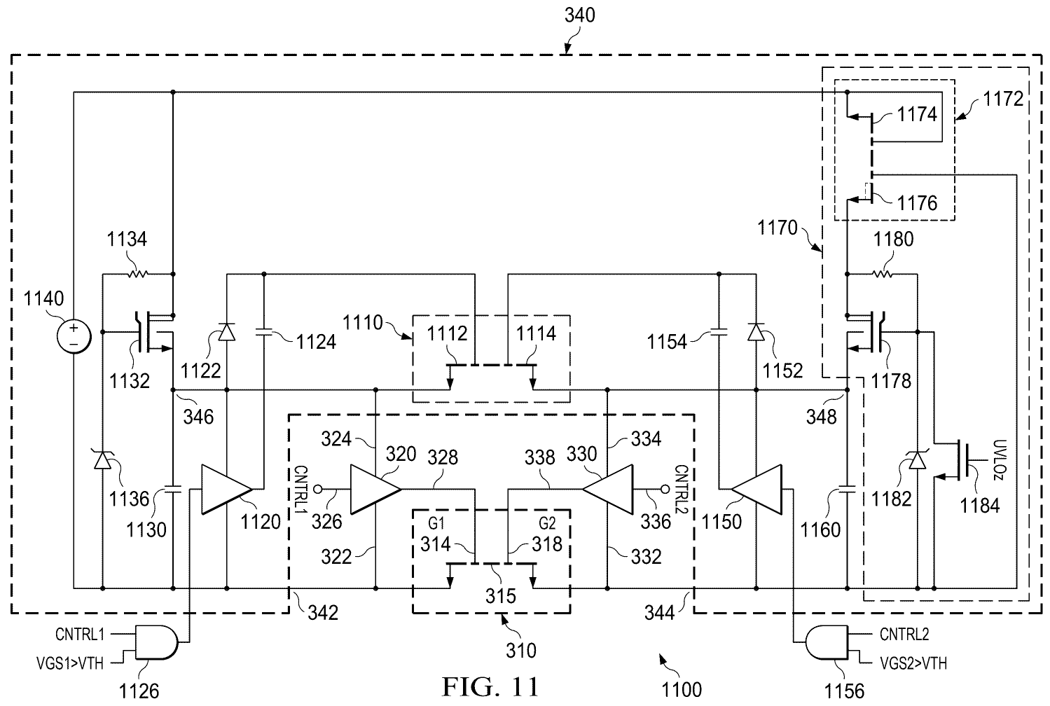

FIG. 11 is a schematic diagram of an example of a circuit 1100 including bidirectional switch 310 and circuits for controlling bidirectional switch 310. Circuit 1100 may be an example of circuit 900, and may include first driver 320 and second driver 330 as described above with respect to FIGS. 3 and 9. In circuit 1100, bias generator 340 may include a charge transfer circuit that includes an auxiliary bidirectional switch 1110 and the corresponding control circuits, such as auxiliary drivers 1120 and 1150 used to drive the dual gates of auxiliary bidirectional switch 1110. The charge transfer circuit can transfer charge, for example, from a voltage supply 1140 and/or a capacitor 1130 to a capacitor 1160. Bias generator 340 may also include a startup circuit 1170 that can properly bias auxiliary driver 1150 in the event capacitor 1160 has a low voltage at the startup of bidirectional switch 310.

In the illustrated example, bias generator 340 may include voltage supply 1140 coupled to a first voltage regulator that includes a transistor 1132, a resistor 1134 coupled between the drain and gate of transistor 1132, and a Zener diode 1136 coupled to the gate of transistor 1132. Transistor 1132 may function as a source follower. The source of transistor 1132 may be coupled to capacitor 1130 and first bias output 346. The first voltage regulator can generate, from voltage supply 1140, a bias voltage at first bias output 346 to bias first driver 320 and auxiliary driver 1120.

Voltage supply 1140 may also be coupled to startup circuit 1170. Startup circuit 1170 may include a bidirectional switch 1172 and a second voltage regulator. The second voltage regulator may include a source follower that may include a transistor 1178 and a resistor 1180 coupled between the drain and gate of transistor 1178, a Zener diode 1182 coupled to the gate of transistor 1178, and a switch 1184 that may control the gate of transistor 1178. The source of transistor 1178 may be coupled to second bias output 348 and capacitor 1160. Bidirectional switch 1172 may include an E-mode transistor 1174 and a D-mode transistor 1176 sharing a common drain or with their drains coupled together.

Auxiliary bidirectional switch 1110 may be a common-drain bidirectional switch that is similar to bidirectional switch 310 or includes two transistors with their drain terminals connected together. For example, auxiliary bidirectional switch 1110 may include a transistor 1112 and a transistor 1114. As described above, transistors 1112 and 1114 may be HEMTs, such as GaN-based HEMTs. The source of transistor 1112 may be coupled to first bias output 346, while the source of transistor 1114 may be coupled to second bias output 348. The gate of transistor 1112 may be driven by the output of auxiliary driver 1120 through a capacitor 1124 (e.g., a charge pump capacitor), and the gate of transistor 1114 may be driven by the output of auxiliary driver 1150 through a capacitor 1154. Capacitors 1124 and 1154 can provide gate drive voltages that may be higher than the outputs of auxiliary drivers 1120 and 1150 and the sources of transistors 1112 and 1114. The charge transfer circuit may also include a diode 1122 coupled between the gate and source of transistor 1112, and a diode 1152 coupled between the gate and source of transistor 1114. Diodes 1122 and 1152 can bring up the voltage level at the gate of transistor 1112 or 1114 when the output of auxiliary driver 1120 or 1150 is at a low voltage level. After bidirectional switch 310 is turned on by drivers 320 and 330, auxiliary bidirectional switch 1110 can also be turned on by auxiliary drivers 1120 and 1150 that are biased in the same manner as drivers 320 and 330, respectively, such that charge may be transferred from voltage supply 1140 and/or capacitor 1130 to capacitor 1160 thought auxiliary bidirectional switch 1110 that may have a low loss in the enabled state, to replenish capacitor 1160 so that second driver 330 may be properly biased.

Startup circuit 1170 can properly bias second driver 330 in the event capacitor 1160 has a low voltage level at the startup of bidirectional switch 310. For example, at the startup, capacitor 1130 may have a voltage level regulated by the first voltage regulator based on input from voltage supply 1140, such that first driver 320 may be properly biased and may be able to turn on the first transistor of bidirectional switch 310, but capacitor 1160 may be at a low voltage level such that second driver 330 may not be properly biased and thus may not be able to drive the gate of the second transistor of bidirectional switch 310 to turn on the second transistor of bidirectional switch 310. Bidirectional switch 1172 and the second voltage regulator of startup circuit 1170 can charge capacitor 1160 before startup so that second driver 330 may be properly biased to turn on the second transistor of bidirectional switch 310 at startup. For example, when the voltage level of capacitor 1160 is low, D-mode transistor 1176 may be in the ON state because the voltage difference between the gate and source of D-mode transistor 1176 is greater than the negative threshold voltage (e.g., about −20 V). The gate and source of E-mode transistor 1174 may be at a voltage level that is the sum of the supply voltage of voltage supply 1140 and the voltage level of first terminal 312, which may be high initially or may reach a high level when the second transistor of bidirectional switch 310, with gate and source at the same voltage, operates similarly to a forward-biased diode and conducts a current that flows through first transistor of bidirectional switch 310, which is turned on by first driver 320. Thus, the source of D-mode transistor 1074 may be at a voltage level close to the voltage level at the positive terminal of voltage supply 1140. Switch 1184 may be turned off when the voltage level of capacitor 1160 is low, so that transistor 1178 of the source follower of the second voltage regulator may be turned on. Therefore, a current may flow from voltage supply 1140 through bidirectional switch 1172 and the second voltage regulator to capacitor 1160 to charge capacitor 1160, such that second driver 330 may be properly biased to turn on the second transistor of bidirectional switch 310, thereby turning on bidirectional switch 310.

After capacitor 1160 is at a high level and bidirectional switch 310 is turned on, switch 1184 may be turned on to bring the voltage level at the gate of transistor 1178 down to turn off the source follower, and auxiliary bidirectional switch 1110 may be turned on by auxiliary drivers 1120 and 1150 controlled by control gates 1126 and 1156, respectively. For example, when the V_{GS} of the first transistor of bidirectional switch 310 is greater than a threshold value (e.g., higher than the Miller plateau), control gate 1126 may control auxiliary driver 1120 to turn on transistor 1112. Similarly, when the V_{GS} of the second transistor of bidirectional switch 310 is greater than a threshold value (e.g., higher than the Miller plateau), control gate 1156 may control auxiliary driver 1150 to turn on transistor 1114. Thus, charges may be transferred between capacitor 1130 (and first bias output 346) and capacitor 1160 (and second bias output 348) through auxiliary bidirectional switch 1110 that may have a low voltage drop and thus a low power loss. Since the second source follower of startup circuit 1170 is turned off, charges may not be transferred from voltage supply 1140 to capacitor 1160 through a path including bidirectional switch 1172 and the second voltage regulator, which may have a large voltage drop and a high power loss.

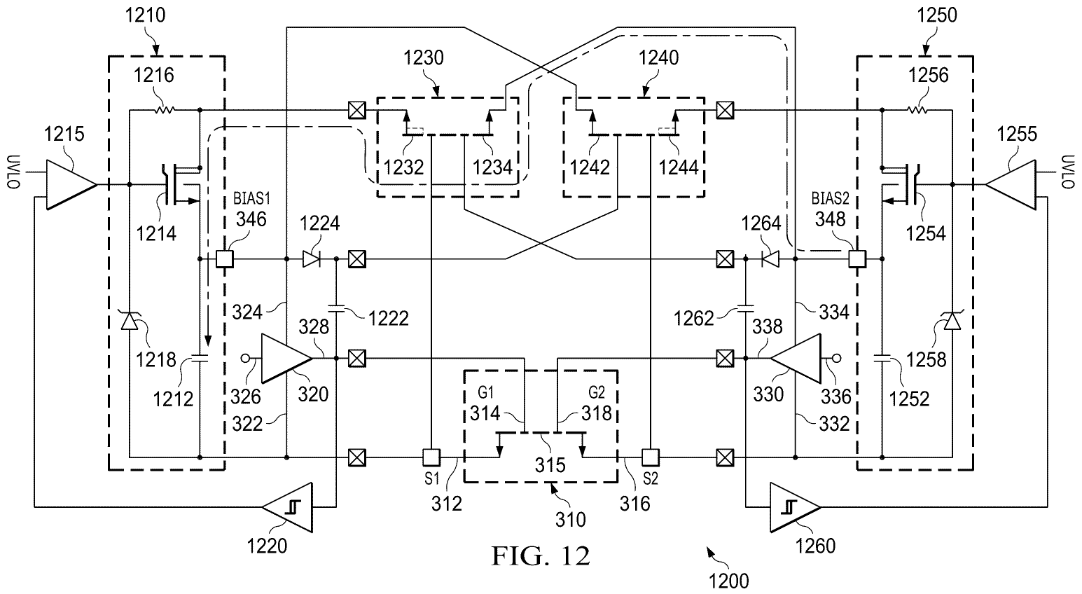

FIG. 12 is a schematic diagram of an example of a circuit 1200 including bidirectional switch 310 and circuits for controlling bidirectional switch 310. Circuit 1200 may be another example of circuit 900, and may include first driver 320 and second driver 330 as described above with respect to FIGS. 3 and 9. In circuit 1200, the bias generator may include bootstrap circuits 1210 and 1250, and bidirectional switches 1230 and 1240, which may together form charge transfer circuits. The charge transfer circuits can transfer charges from a first voltage source (e.g., an isolated voltage source) for a first driver to a second voltage source (e.g., a bootstrap capacitor) for a second driver of bidirectional switch 310, before and after bidirectional switch 310 is turned on (for both switch startup and charge spill-over). Bootstrap circuits 1210 and 1250 can regulate the bias voltages at first bias output 346 and second bias output 348 for both switch startup and charge spill-over.

In the illustrated example, bootstrap circuit 1210 may include a first voltage source 1212 (which may be a capacitor or an isolated voltage source) coupled between bias terminal 324 and reference terminal 322 of first driver 320, and a voltage regulator that may include a source follower formed by a transistor 1214 and a resistor 1216 coupled between the drain and source of transistor 1214, and a Zener diode 1218 coupled between the gate of transistor 1214 and reference terminal 322 of first driver 320 (and first terminal 312 (S1) of bidirectional switch 310). The gate of transistor 1214 may be controlled by a driver 1215, which may in turn be controlled by a detector 1220 that may detect the voltage difference between the gate and source (V_{GS}) of the first transistor of bidirectional switch 310. Bootstrap circuit 1250 may include a second voltage source 1252 (which may be a capacitor or an isolated voltage source) coupled between bias terminal 334 and reference terminal 332 of second driver 330 (and second terminal 316 (S2) of bidirectional switch 310), and a voltage regulator that may include a source follower formed by a transistor 1254 and a resistor 1256 coupled between the drain and source of transistor 1254, and a Zener diode 1258 coupled between the gate of transistor 1254 and reference terminal 332 of second driver 330. The gate of transistor 1254 may be controlled by a driver 1255, which may in turn be controlled by a detector 1260 that may detect the voltage difference between the gate and source (V_{GS}) of the second transistor of bidirectional switch 310.

Bidirectional switch 1230 may include a D-mode transistor 1232 and an E-mode transistor 1234 sharing a common drain or with their drains coupled together. The source and gate of D-mode transistor 1232 may be coupled to the drain of transistor 1214 and first terminal 312 (S1) of bidirectional switch 310, respectively. The source and gate of E-mode transistor 1234 may be coupled to second voltage source 1252 (and second bias output 348) and a capacitor 1262 (and a diode 1264), respectively. Bidirectional switch 1240 may include a D-mode transistor 1244 and an E-mode transistor 1242 sharing a common drain or with their drains coupled together. The source and gate of D-mode transistor 1244 may be coupled to the drain of transistor 1254 and second terminal 316 (S2) of bidirectional switch 310, respectively. The source and gate of E-mode transistor 1242 may be coupled to first voltage source 1212 (and first bias output 346) and a capacitor 1222 (and a diode 1224), respectively.

During operations of bidirectional switch 310, first voltage source 1212 and second voltage source 1252 can bias first driver 320 and second driver 330, so that bidirectional switch 310 may be turned on by first driver 320 and second driver 330. After bidirectional switch 310 is turned on, a charge transfer circuit may be enabled (e.g., by enabling a source follower in bootstrap circuit 1210 or 1250) to transfer charge between first voltage source 1212 and second voltage source 1252, thereby restoring charges lost on a voltage source (e.g., a capacitor) during operations. In some circumstances, the voltage level of a voltage source may be low at the startup of bidirectional switch 310, a charge transfer circuit may be enabled (e.g., by enabling a source follower in bootstrap circuit 1210 or 1250) to transfer charge between first voltage source 1212 and second voltage source 1252, such that the voltage source with low initial voltage level may be charged to a higher voltage level to bias the driver properly, thereby turning on the corresponding transistor of bidirectional switch 310.

In one example, second voltage source 1252 may include a voltage supply (e.g., an isolated voltage supply) and first voltage source 1212 may include a capacitor. Charges may be transferred between second voltage source 1252 and first voltage source 1212 though bidirectional switch 1230 and a source follower formed by transistor 1214 during startup and charge transfer (e.g., spill-over). For example, when first terminal 312 (S1) of bidirectional switch 310 has a first voltage level (e.g., several hundred volts, such as about 600 V) higher than the second voltage level (e.g., 0 V) of second terminal 316 (S2) of bidirectional switch 310, the common drain region 315 of bidirectional switch 310 may be at about the first voltage level (with one threshold voltage drop) due to the first transistor of bidirectional switch 310 having both gate and source at the first voltage level. Second driver 330 may be properly biased by second voltage source 1252 and thus may be able to turn on the second transistor of bidirectional switch 310. Therefore, the voltage level at second terminal 316 (S2) of bidirectional switch 310 may increase to a level close to the first voltage level, and the voltage level at second bias output 348 may be equal to the sum of the first voltage level and the supply voltage of second voltage source 1252. When the second transistor of bidirectional switch 310 is turned on by second driver 330, transistor 1234 can also be turned on by second driver 330 through capacitor 1262, which may boost the output voltage of second driver 330 to a level higher than the voltage level of the source of transistor 1234 by at least the threshold voltage of transistor 1234. As described above, a diode 1264 can bring up the voltage level at the gate of transistor 1234 when the output of second driver 330 is at a low level. D-mode transistor 1232 may be conductive initially to increase the voltage level at the source of D-mode transistor 1232, until the source of D-mode transistor 1232 is at a level higher than the voltage level of the gate of D-mode transistor 1232 (which may be at the first voltage level) by a threshold voltage (e.g., about 20 V). The voltage level at the source of D-mode transistor 1232 may be regulated by the voltage regulator in bootstrap circuit 1210, such that the capacitor of first voltage source 1212 may be charged to a higher voltage level if the capacitor has a low initial voltage or is partially depleted during operations, and thus the output voltage at first bias output 346 may be at a proper level (e.g., about 5 V above the voltage level at first terminal 312 (S1) of bidirectional switch 310) to provide a supply voltage to first driver 320 to fully turn on the first transistor of bidirectional switch 310. Therefore, bidirectional switch 1230 and the voltage regulator in bootstrap circuit 1210 may be used for both charge transfer and startup when bidirectional switch 310 has a higher voltage level at first terminal 312 before bidirectional switch 310 is turned on.

When second terminal 316 (S2) of bidirectional switch 310 has a first voltage level (e.g., several hundred volts such as about 600 V) higher than the voltage level (e.g., about 0 V) of first terminal 312 (S1) of bidirectional switch 310, the voltage level at second bias output 348 may be equal to the sum of the first voltage level and the supply voltage of second voltage source 1252. The common-drain region of bidirectional switch 310 may be at a level close to the first voltage level (with one threshold voltage drop) due to the second transistor of bidirectional switch 310 having gate and source having the first voltage level. Second driver 330 may be properly biased by second voltage source 1252 and thus may be able to turn on the second transistor of bidirectional switch 310. But first terminal 312 (S1) may still be at a low level because the first transistor or bidirectional switch 310 may not be turned on (e.g., due to a control signal at the input of first driver 320 or a low bias voltage at bias terminal 324). When the second transistor of bidirectional switch 310 is turned on by second driver 330, transistor 1234 can also be turned on by second driver 330 through capacitor 1262, which may boost the output voltage of second driver 330 to a level higher than the source of transistor 1234 by at least the threshold voltage of transistor 1234 at the gate voltage of transistor 1234. D-mode transistor 1232 may be conductive initially to increase the voltage level (which may be low initially) at the source of D-mode transistor 1232, until the voltage level at the source of D-mode transistor 1232 is at a level (e.g., about 20 V) higher than the gate of D-mode transistor 1232 (e.g., at about 0 V) by a threshold voltage (e.g., about 20 V). The voltage level at the source of D-mode transistor 1232 may be regulated by the voltage regulator in bootstrap circuit 1210, such that the capacitor of first voltage source 1212 may be charged to a higher voltage level if the capacitor has a low initial voltage or is partially depleted during operation, and the output voltage at first bias output 346 may be at a proper level (e.g., about 5 V above the voltage level at first terminal 312 (S1) of bidirectional switch 310) to provide a supply to first driver 320 to turn on the first transistor of bidirectional switch 310, such that first terminal 312 (S1) of bidirectional switch 310 may be at the first voltage level (e.g., about 600 V). Therefore, bidirectional switch 1230 and the voltage regulator in bootstrap circuit 1210 may also be used for both charge transfer and startup when bidirectional switch 310 has a higher voltage level at second terminal 316 before bidirectional switch 310 is turned on.

Detector 1220 may detect the V_{GS} of the first transistor of bidirectional switch 310. Before the V_{GS} of the first transistor of bidirectional switch 310 is greater than a threshold value (e.g., above the Miller plateau voltage), the first transistor may not be fully turned on, and the voltage level at first terminal 312 (S1) may still be much lower than the voltage level at second terminal 316 (S2) (e.g., when second terminal 316 has a higher initial voltage level), it may be desirable to draw charge from first voltage source 1212 (e.g., a capacitor) to power first driver 320, rather than through bidirectional switch 1230 (which may have a large voltage drop and thus a high loss). Detector 1220 may detect the lower V_{GS} and control driver 1215 to turn off the source follower so that charge may not be drawn through bidirectional switch 1230 to power first driver 320. When the V_{GS} of the first transistor of bidirectional switch 310 is greater than a threshold value (e.g., above the Miller plateau voltage), the first transistor of bidirectional switch 310 may be fully turned on, such that the voltage level at first terminal 312 may be similar to the voltage level at second terminal 316, and voltage drop on bidirectional switch 1230 may be low. Detector 1220 may detect the higher V_{GS} and control driver 1215 to turn on the source follower to draw current through bidirectional switch 1230 and the source follower for charge transfer (spill-over).

Driver 1215 may also be controlled by an under voltage lockout (UVLO) signal. When the voltage level of the capacitor of first voltage source 1212 is low, the UVLO signal may control driver 1215 to turn on transistor 1214 of the source follower. Therefore, a current may flow from second voltage source 1252 through bidirectional switch 1230 and the source follower to the capacitor of first voltage source 1212 to charge the capacitor, such that first driver 320 may be properly biased to turn on the first transistor of bidirectional switch 310. When the capacitor of first voltage source 1212 is at a high level, driver 1215 may bring the voltage level at the gate of transistor 1214 down and turn off the source follower, so that current may be drawn from the capacitor of first voltage source 1212, rather than through bidirectional switch 1230 (which may have a large voltage drop and a high power loss as describe), to power first driver 320.

Therefore, when the voltage level of the capacitor of first voltage source 1212 is below a threshold value, transistor 1214 may be turned on by driver 1215 to charge the capacitor through bidirectional switch 1230. When the voltage level of the capacitor of first voltage source 1212 is at or above the threshold value, driver 1215 may turn off transistor 1214 if the V_{GS} of the first transistor of bidirectional switch 310 detected by detector 1220 is below the threshold value of the first transistor (and thus the first transistor may be in pre-Miller condition and may not be fully turned on), and may turn on transistor 1214 for charge transfer (spill-over) through bidirectional switch 1230 when the V_{GS} of the first transistor of bidirectional switch 310 detected by detector 1220 is above the threshold value of the first transistor (e.g., above the Miller plateau) and thus the first transistor is fully turned on, so that the voltage drop and the power loss on the charge transfer path can be low.

When first voltage source 1212 includes a voltage supply and the second voltage source 1252 is a capacitor, bidirectional switch 1240 and the second voltage regulator in bootstrap circuit 1250 may be used for charge transfer (spill-over) and startup in manners similar to the manners described above with respect to bidirectional switch 1230 and the first voltage regulator in bootstrap circuit 1210. Detector 1260 and driver 1255 may function in similar manners as detector 1220 and driver 1215, respectively to control the source follower in bootstrap circuit 1250.

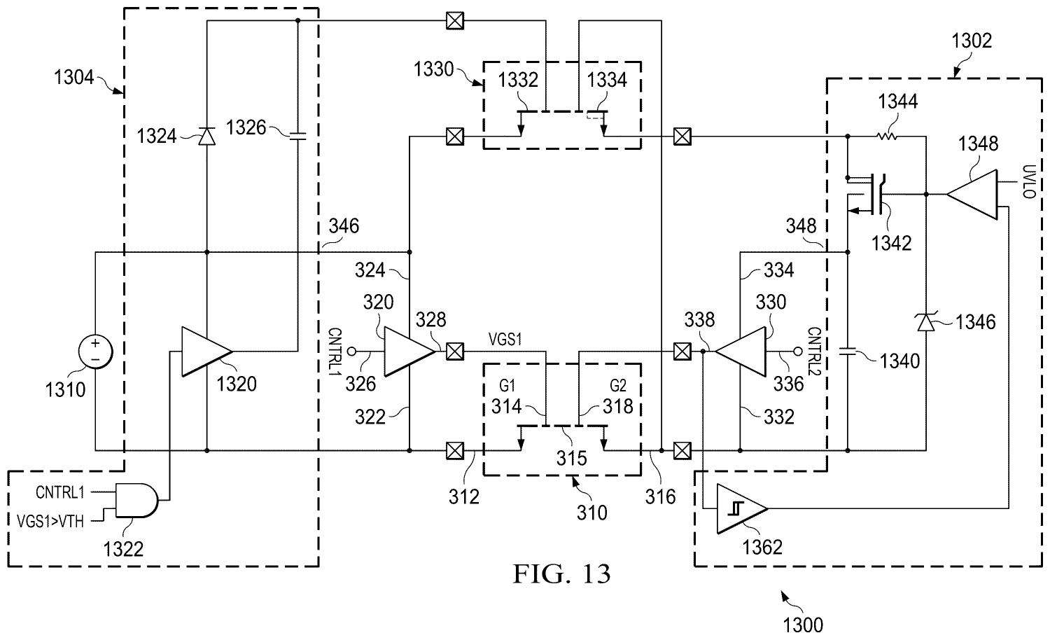

FIG. 13 is a schematic diagram of an example of a circuit 1300 including bidirectional switch 310 and circuits for controlling bidirectional switch 310. Circuit 1300 may be another example of circuit 900, and may include first driver 320 and second driver 330 as described above with respect to FIGS. 3 and 9. In circuit 1300, the bias generator may include a bootstrap circuit 1302, a voltage supply 1310, and a charge transfer circuit that may include a bidirectional switch 1330 and a driver circuit 1304. First driver 320 may be powered by voltage supply 1310, which may include an isolated power supply as described above. The charge transfer circuit can transfer charges from voltage supply 1310 to a second voltage source (e.g., including a capacitor 1340) for second driver 330.

Bidirectional switch 1330 may include an E-mode transistor 1332 and a D-mode transistor 1334 sharing a common drain or with their drains coupled together. The source and gate of D-mode transistor 1334 may be coupled to bootstrap circuit 1302 and second terminal 316 (S2) of bidirectional switch 310, respectively. The source and gate of E-mode transistor 1332 may be coupled to voltage supply 1310 (and second bias output 348) and a capacitor 1326 (and a diode 1324), respectively. Bidirectional switch 1330 may be controlled by driver circuit 1304. Driver circuit 1304 may include an auxiliary driver 1320, a control gate 1322, diode 1324, and capacitor 1326. Auxiliary driver 1320 may have a reference terminal coupled to first terminal 312 (S1) of bidirectional switch 310, and a bias terminal coupled to voltage supply 1310 (and first bias output 346). Auxiliary driver 1320 may be controlled by control gate 1322 to drive the gate of E-mode transistor 1332 through capacitor 1326 (e.g., a charge pump capacitor). As described above, diode 1324 can pull up the gate of transistor 1332 when the output of auxiliary driver 1320 is low. Bootstrap circuit 1302 may include a capacitor 1340 and a voltage regulator. The voltage regulator may include a source follower formed by a transistor 1342 and a resistor 1344 coupled between the drain and gate of transistor 1342, and a Zener diode 1346. Transistor 1342 of the source follower may be controlled by a driver 1348, which may be controlled by the output of a detector 1362 and a control signal UVLO.

In one example, first terminal 312 (S1) of bidirectional switch 310 may have a first voltage level (e.g., several hundred volts, such as about 600 V) higher than the second voltage level (e.g., about 0 V) of second terminal 316 (S2) of bidirectional switch 310. Before bidirectional switch 310 is turned on, common drain region 315 of bidirectional switch 310 may be at close to the first voltage level (with one threshold voltage drop) due to the first transistor of bidirectional switch 310 having gate and source at the first voltage level, but second terminal 316 (S2) of bidirectional switch 310 may remain at a low voltage level. Before the V_{GS} of the first transistor of bidirectional switch 310 reaches a threshold and the V_{GS} of the second transistor of bidirectional switch 310 reaches a threshold, auxiliary driver 1320 may not be controlled to turn on transistor 1332 of bidirectional switch 1330, and detector 1362 may control driver 1348 to turn off transistor 1342, such that current may not flow on a path from voltage supply 1310 to capacitor 1350 through the charge transfer circuit. Before bidirectional switch 310 is turned on, the path may have a large voltage drop due to the large voltage difference between first terminal 312 (S1) and second terminal 316 (S2) of bidirectional switch 310, and thus may have a high power loss if a current flows on this path.

To turn on bidirectional switch 310, first driver 320, which may be powered by voltage supply 1310, may be controlled to drive the gate of the first transistor of bidirectional switch 310 to turn on the first transistor. Second driver 330 may be powered by capacitor 1340 and may be controlled to turn on the second transistor of bidirectional switch 310. Therefore, the voltage levels of second terminal 316 (S2) and the gate of transistor 1334 may be at the first voltage level (e.g., about 600 V) of first terminal 312 (S1). After bidirectional switch 310 is turned on, for example, when the V_{GS} is greater than the threshold voltage V_{TH} (e.g., above the Miller plateau voltage) for both transistors of bidirectional switch, auxiliary driver 1320, which is biased by voltage supply 1310, may be controlled by control gate 1322 to turn on transistor 1332. The source of transistor 1332 may be at a level that is equal to the sum of the first voltage level at first terminal 312 and the supply voltage of voltage supply 1310. Because transistor 1334 is a D-mode transistor, bidirectional switch 1330 may be in the ON state and have a low resistance, until the voltage level at the source of 1334 is about a threshold level (e.g., about 20 V) higher than the voltage level (e.g., about 600 V) at the gate of transistor 1334. Therefore, the voltage level at the source of transistor 1332 may be about the same as the voltage level at the source of transistor 1334.

Detector 1362 may detect the V_{GS} of the second transistor of bidirectional switch 310 and may control driver 1348 to turn on transistor 1342 because the second transistor of bidirectional switch 310 is fully turned on and thus the V_{GS} of the second transistor of bidirectional switch 310 may be greater than a threshold value (e.g., above the Miller plateau). When transistor 1342 is turned on, the voltage difference between the source and gate of transistor 1334 (e.g., up to about 20 V) may be regulated by the voltage regulator of bootstrap circuit 1302 to an appropriate voltage level (e.g., about 5V) at second bias output 348, so that charges may be transferred to capacitor 1340 to replenish capacitor 1340. Due to the low voltage drop on the charge transfer path, the charge transfer may have a low loss.

In the event the voltage level of capacitor 1340 is low during the startup of bidirectional switch 310, second driver 330 may not be able to turn on the second transistor of bidirectional switch 310 initially, and the voltage level at second terminal 316 may remain low (e.g., about 0 V). The gate and source of transistor 1332 have the same voltage, and the common drain of bidirectional switch 1330 may have a voltage level close to the voltage level of source and gate of transistor 1332 (with one threshold voltage drop). Alternatively or additionally, auxiliary driver 1320, which is biased by voltage supply 1310, may be controlled by control gate 1322 to turn on transistor 1332. Because transistor 1334 is a D-mode transistor, bidirectional switch 1330 may be in the ON state, until the voltage level at the source of transistor 1334 is about a threshold level higher than the voltage level (e.g., about 0 V) at the gate of transistor 1334. Driver 1348 may be controlled by a control signal UVLO to turn on transistor 1342 of the source follower in the voltage regulator when the voltage level of capacitor 1340 is low. When transistor 1342 is turned on, the voltage difference between the gate and source of transistor 1334 may be regulated by the voltage regulator of bootstrap circuit 1302 to an appropriate voltage level (e.g., about 5V above the voltage level at second terminal 316) at second bias output 348, so that capacitor 1340 may be charged to a level that may properly bias second driver 330 to turn on the second transistor of bidirectional switch 310 (and thus bidirectional switch 310). After the voltage of capacitor 1340 is greater than a threshold value, driver 1348 may be controlled to turn off transistor 1342. Therefore, the voltage regulator of bootstrap circuit 1302, bidirectional switch 1330, and driver circuit 1304 may be used for both charge transfer and startup of bidirectional switch 310 when first terminal 312 has a higher voltage than second terminal 316 before bidirectional switch 310 is turned on.

In another example, second terminal 316 (S2) of bidirectional switch 310 may have a first voltage level (e.g., several hundred volts, such as about 600 V) higher than the second voltage level (e.g., 0 V) of first terminal 312 (S1) of bidirectional switch 310. Before bidirectional switch 310 is turned on, the common drain region of bidirectional switch 310 may be at the first voltage level (with one threshold voltage drop) due to the second transistor of bidirectional switch 310 having gate and source at the first voltage level, but first terminal 312 (S1) of bidirectional switch 310 may remain at a low voltage level. Before the V_{GS} of the first transistor of bidirectional switch 310 reaches a threshold (e.g., above the Miller plateau voltage) and the V_{GS} of the second transistor of bidirectional switch 310 reaches a threshold (e.g., above the Miller plateau voltage), auxiliary driver 1320 may not be controlled to turn on transistor 1332 of bidirectional switch 1330, and detector 1362 may control driver 1348 to turn off transistor 1342, such that current may not flow on a path from voltage supply 1310 to capacitor 1340 through bidirectional switch 1330. The path may have a large voltage drop due to the large voltage difference between first terminal 312 (S1) and second terminal 316 (S2) of bidirectional switch 310, and thus may have a high power loss if a current flows on this path.

To turn on bidirectional switch 310, first driver 320, which may be biased by voltage supply 1310, may be controlled to drive the gate of the first transistor of bidirectional switch 310 to turn on the first transistor. Second driver 330 may be biased by capacitor 1340 and may be controlled to turn on the second transistor of bidirectional switch 310. Therefore, the voltage level of first terminal 312 (S1) may rise from about 0 V to the first voltage level (e.g., about 600 V) of second terminal 316 (S2). After bidirectional switch 310 is turned on, for example, when the V_{GS} is greater than the threshold voltage (e.g., above the Miller plateau voltage) for both transistors of bidirectional switch 310, auxiliary driver 1320, which is biased by voltage supply 1310, may be controlled by control gate 1322 to turn on transistor 1332. Since transistor 1334 is a D-mode transistor, bidirectional switch 1330 may be in the ON state, until the voltage level at the source of transistor 1334 is about a threshold level (e.g., about 20 V) higher than the voltage level (e.g., about 600 V) at the gate of transistor 1334. Detector 1362 may detect the V_{GS} of the second transistor of bidirectional switch and may control driver 1348 to turn on transistor 1342. Therefore, the voltage difference between the gate and source of transistor 1334 may be regulated by the voltage regulator of bootstrap circuit 1302 to an appropriate voltage level (e.g., about 5V above the first voltage level) at second bias output 348, so that charges may be transferred to capacitor 1340 to replenish capacitor 1340. Since both first terminal 312 (S1) and second terminal 316 (S2) are at about the first voltage level, the source of transistor 1332 may be at a voltage level that is about the sum of the first voltage level and the voltage of voltage supply 1310, and the source of transistor 1334 may be at a level that is about the sum of the first voltage level and a voltage at or below the absolute value of the threshold voltage of transistor 1334. Therefore, the voltage drop on bidirectional switch 1330 is low, and the charge transfer may have a low loss.

If the voltage level of capacitor 1340 is low during the startup bidirectional switch 310, the second transistor of bidirectional switch 310 may not be turned on initially, and the voltage level at first terminal 312 may remain low. First driver 320 may turn on the first transistor of bidirectional switch 310, such that the voltage level at first terminal 312 (S1) may be close to the first voltage level at second terminal 316 (with one threshold voltage drop) due to the gate and source of the second transistor of bidirectional switch 310 being at the first voltage level. Auxiliary driver 1320, which is biased by voltage supply 1310, may be controlled by control gate 1322 to turn on transistor 1332. Therefore, bidirectional switch 1330 may be in the ON state, until the voltage level at the source of D-mode transistor 1334 is about a threshold level (e.g., about 20 V) higher than the voltage level (e.g., about 600 V) at the gate of transistor 1334. When the voltage level of capacitor 1340 is low, driver 1348 may be controlled by a control signal UVLO to turn on transistor 1342 of the source follower in the voltage regulator. Therefore, the voltage difference between the gate and source of transistor 1334 may be regulated by the voltage regulator of bootstrap circuit 1302 to an appropriate voltage level (e.g., about 5V above the voltage level at second terminal 316) at second bias output 348, so that capacitor 1340 may be charged to a level that may properly bias second driver 330 to turn on the second transistor of bidirectional switch 310 (and thus bidirectional switch 310). Therefore, the voltage regulator of bootstrap circuit 1302, bidirectional switch 1330, and driver circuit 1304 may be used for both charge transfer and startup of bidirectional switch 310 when first terminal 312 has a lower higher voltage than second terminal 316 before bidirectional switch 310 is turned on.

Therefore, in circuit 1300, when the voltage level of capacitor 1340 is below a threshold value, transistor 1342 may be turned on by driver 1348 to charge capacitor 1340 through bidirectional switch 1330. When the voltage level of capacitor 1340 is at or above the threshold value, driver 1348 may turn off transistor 1342 if the V_{GS} of the second transistor of bidirectional switch 310 detected by detector 1362 is below the threshold value of the second transistor (and thus the second transistor may be in the pre-Miller condition and may not be fully turned on), and may turn on transistor 1342 for charge transfer (spill-over) through bidirectional switch 1330 when the V_{GS} of the second transistor of bidirectional switch 310 detected by detector 1362 is above the threshold value of the second transistor (e.g., above the Miller plateau) and thus the second transistor is fully turned on, so that power loss on the charge transfer path can be low.

As described above, bidirectional power switches disclosed herein may be used in a power switch matrix or switch network, such as a N×M power switch network. In one example, the power switch network may be used as a matrix converter for AC power conversion. Using techniques disclosed herein, the number of power supplies for biasing a large number of bidirectional switches in a switch matrix can be significantly reduced due to the sharing of the same voltage supply for both drivers of a dual-gate bidirectional switch that may have different reference voltages.

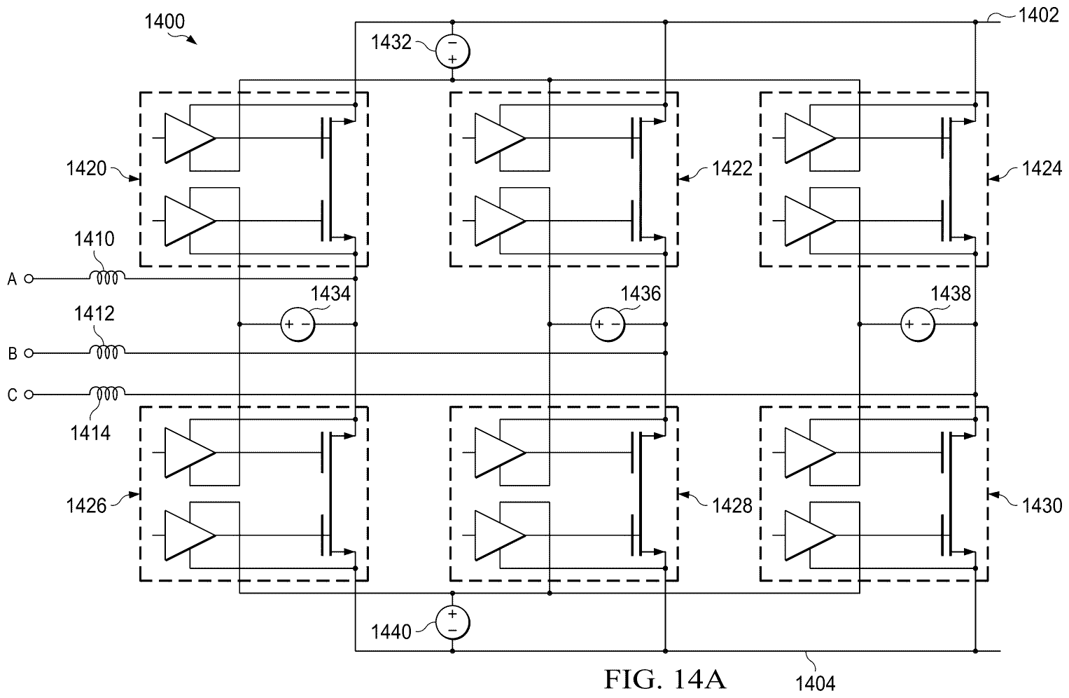

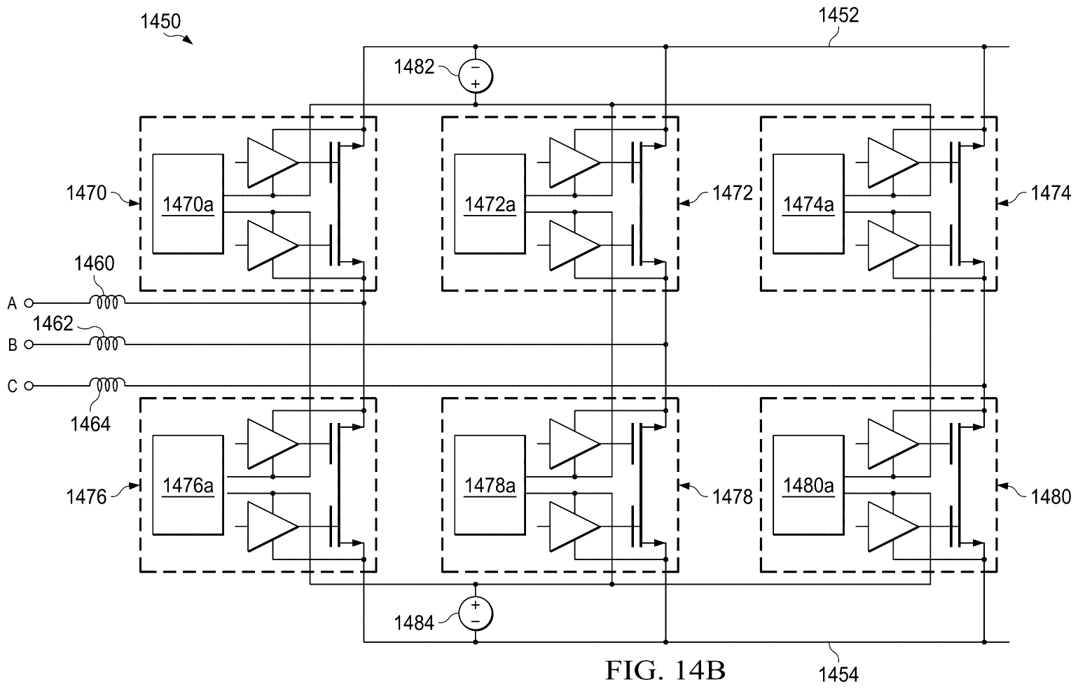

FIG. 14A is a schematic diagram of an example of a matrix converter 1400. Matrix converter 1400 may include three input ports and two output rails connected by a switch matrix that includes 6 bidirectional switches, such as GaN HEMT-based dual-gate bidirectional switches described above. The three input ports may include input ports A, B, and C. Each input port may be coupled to the switch matrix through an inductor 1410, 1412, or 1414. The two output rails may include a first output rail 1402 and a second output rail 1404. The switch matrix may include bidirectional switches 1420, 1422, and 1424 coupled between first output rail 1402 and input ports A, B, and C, respectively. The switch matrix may also include bidirectional switches 1426, 1428, and 1430 coupled between second output rail 1404 and input ports A, B, and C, respectively.

In the illustrated example, each bidirectional switch may include drive circuits that use two voltage sources for biasing two drivers of the bidirectional switches as describe above with respect to FIG. 2. Because one terminal of each of bidirectional switches 1420, 1422, and 1424 is coupled to first output rail 1402 and has the same voltage level (and thus the same reference voltage for the driver), the drive circuits of bidirectional switches 1420, 1422, and 1424 may share one isolated voltage supply 1432. Similarly, because one terminal of each of bidirectional switches 1426, 1428, and 1430 is coupled to second output rail 1404 and has the same voltage level, the drive circuits of bidirectional switches 1426, 1428, and 1430 may share one isolated voltage supply 1440. One terminal of bidirectional switch 1420 and one terminal of bidirectional switch 1426 may both be coupled to input port A through inductor 1410 and have the same voltage level. Therefore, an isolated voltage supply 1434 may be shared by the drive circuits of bidirectional switches 1420 and 1426. One terminal of bidirectional switch 1422 and one terminal of bidirectional switch 1428 may both be coupled to input port B through inductor 1412 and have the same voltage level. Therefore, an isolated voltage supply 1436 may be shared by the drive circuits of bidirectional switches 1422 and 1428. One terminal of bidirectional switch 1424 and one terminal of bidirectional switch 1430 may both be coupled to input port C through inductor 1414 and have the same voltage level. Therefore, an isolated voltage supply 1438 may be shared by the drive circuits of bidirectional switches 1422 and 1428. As such, five isolated voltage supplies can properly bias the drive circuits of matrix converter 1400.

FIG. 14B is a schematic diagram of an example of a matrix converter 1450 with bias supply sharing. As matrix converter 1400, matrix converter 1450 may include three input ports and two output rails connected by a switch matrix having 6 bidirectional switches, such as GaN HEMT-based dual-gate bidirectional switches described above. The three input ports may include input ports A, B, and C. Each input port may be coupled to the switch matrix though an inductor 1460, 1462, or 1464. The two output rails may include a first output rail 1452 and a second output rail 1454. The switch matrix may include bidirectional switches 1470, 1472, and 1474 coupled between first output rail 1452 and input ports A, B, and C, respectively. The switch matrix may also include bidirectional switches 1476, 1478, and 1480 coupled between second output rail 1454 and input ports A, B, and C, respectively.

In the example shown in FIG. 14B, each bidirectional switch may include a bias generator that uses one voltage source to generate two bias voltages for biasing two drivers of the bidirectional switches as describe above with respect to FIGS. 3-13. For example, bidirectional switch 1470 may include a bias generator 1470a, bidirectional switch 1472 may include a bias generator 1472a, bidirectional switch 1474 may include a bias generator 1474a, bidirectional switch 1476 may include a bias generator 1476a, bidirectional switch 1478 may include a bias generator 1478a, and bidirectional switch 1480 may include a bias generator 1480a. In addition, because bidirectional switches 1470, 1472, and 1474 are all coupled to first output rail 1452, the bias generators 1470a, 1472a, and 1474a of, respectively, bidirectional switches 1470, 1472, and 1474 may be coupled to the same isolated voltage supply 1482 to generate bias voltages for biasing the six drivers. Similarly, because bidirectional switches 1476, 1478, and 1480 are all coupled to second output rail 1454, the bias generators 1476a, 1478a, and 1480a of, respectively, bidirectional switches 1476, 1478, and 1480 may be coupled to the same isolated voltage supply 1484 to generate bias voltages for biasing the six drivers. Therefore, two isolated voltage supplies can be used to properly bias all drive circuits of matrix converter 1450. Compared with matrix converter 1400, matrix converter 1450 may use fewer isolated voltage supplies by using the bias generation circuits disclosed herein. When a switch matrix includes more bidirectional switches, the number of isolated voltage supplies used for biasing the drivers can be reduced even more significantly.

FIG. 15 is a cross-sectional view of an example of a monolithic bidirectional switch 1500 including an E-mode transistor/switch and a D-mode transistor/switch sharing a common drain region 1502. Bidirectional switch 1500 can be example of bidirectional switches 1040, 1070, 1172, 1230, 1240, and 1330 of FIGS. 10-13. As shown in FIG. 15, bidirectional switch 1500 may include a substrate (not shown), a channel layer 1510 (e.g., including an undoped GaN layer) grown on the substrate, and a barrier layer 1520 (e.g., including an undoped AlₓGa₍₁₋ₓ₎N layer) over channel layer 1510. The substrate may include, for example, a bulk semiconductor substrate, a semiconductor-on-insulator (SOI) substrate, or another suitable substrate (e.g., a Qromis Substrate Technology (QST) substrate, a sapphire substrate, or another silicon-based substrate). The GaN material in channel layer 1510 has a narrower bandgap than the AlₓGa₍₁₋ₓ₎N material in barrier layer 1520. Due to the bandgap mismatch, large conduction-band offset, and spontaneous and piezoelectric polarization properties of the group-III nitride layers, highly-mobile 2DEG may be generated in channel layer 1510 near the interface of the heterostructure to form a conductive channel in channel layer 1510.

A first gate structure 1530 may be formed over barrier layer 1520. First gate structure 1530 may include a p-GaN layer formed over barrier layer 1520 and a gate electrical contact (e.g., a metal gate electrode) formed on the p-GaN layer, which together form a p-GaN gate structure for the E-mode transistor. The p-GaN layer may be a GaN layer doped with, for example, magnesium (Mg). The p-GaN layer may deplete electrons in the 2DEG channel under the p-GaN gate structure, such that the path between the source and drain may be disabled when no gate drive voltage is applied to the gate electrical contact. When a positive voltage above the gate threshold voltage is applied to the gate electrical contact, the gate structure may attract electrons to replete the 2DEG under the gate structure, thereby turning on the enhancement-mode/E-mode transistor. A first source structure 1532 of the E-mode transistor may be formed on or in barrier layer 1520. A dielectric layer 1536 (e.g., silicon nitride (SiN) covers first gate structure 1530 and first source structure 1532.

Also, a second gate structure 1540 of the depletion-mode/D-mode transistor may be formed over dielectric layer 1536. Second gate structure 1540 can be a metal layer. Second gate structure 1540 may receive a negative voltage to deplete the electrons in the 2DEG channel under second gate structure 1540 to turn off the D-mode transistor. Without the negative voltage, a path between the source and drain of the D-mode transistor can remain enabled. A second source structure 1542 of the D-mode transistor may be formed on or in barrier layer 1520 and covered by the dielectric layer 1536.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion-mode devices, drain-extended devices, enhancement-mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein can describe any feature, structure, or characteristic in the singular or can describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description in order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A circuit comprising:
a first driver having a first bias terminal, a first reference terminal, a first driver input, and a first driver output;
a second driver having a second bias terminal, a second reference terminal, a second driver input, and a second driver output, the second reference terminal; and
a bias generator having a first input, a second input, a first bias output, and a second bias output, the first input coupled to the first reference terminal, the second input coupled to the second reference terminal, the first bias output coupled to the first bias terminal, and the second bias output coupled to the second bias terminal, wherein the bias generator is configurable to generate, based on a supply voltage, a first bias voltage at the first bias output and a second bias voltage at the second bias output.

2. The circuit of claim 1, wherein the bias generator includes:
a maximum voltage selector coupled between the first input and the second input and having an output;
a voltage source having a first supply terminal and a second supply terminal, the first supply terminal coupled to the output of the maximum voltage selector;
a first bootstrap circuit coupled between the second supply terminal and the first bias output; and
a second bootstrap circuit coupled between the second supply terminal and the second bias output.

3. The circuit of claim 2, wherein the maximum voltage selector includes a third transistor and a fourth transistor, the third and fourth transistors having a common-drain terminal coupled to the output of the maximum voltage selector.

4. The circuit of claim 3, wherein:
the third transistor has a third gate and a third source, the third gate coupled to the first driver output, and the third source coupled to the first input of the bias generator; and
the fourth transistor has a fourth gate and a fourth source, the fourth gate coupled to the second driver output, and the fourth source coupled to the second input of the bias generator.

5. The circuit of claim 2, wherein the first bootstrap circuit includes:
a depletion-mode transistor having a drain terminal, a gate terminal, and a source terminal, the drain terminal coupled to the second supply terminal, and the gate terminal coupled to the first input of the bias generator; and
a source follower coupled between the first bias output of the bias generator and the source terminal of the depletion-mode transistor.

6. The circuit of claim 5, wherein:
the first bootstrap circuit includes a diode coupled between the source follower and the source terminal of the depletion-mode transistor;
the source follower includes a control terminal coupled to a control driver; and
the bias generator includes a capacitor coupled between the first bias output and the first input of the bias generator.

7. The circuit of claim 1, wherein the bias generator includes:
a minimum voltage selector coupled between the first input and the second input and having an output;
a voltage source having a first supply terminal and a second supply terminal, the first supply terminal coupled to the output of the minimum voltage selector;
a first bootstrap circuit coupled between the second supply terminal and the first bias output; and
a second bootstrap circuit coupled between the second supply terminal and the second bias output.

8. The circuit of claim 7, wherein the minimum voltage selector includes:
a first switch between the first input and the output of the minimum voltage selector; and
a second switch between the second input and the output of the minimum voltage selector.

9. The circuit of claim 7, wherein the first bootstrap circuit includes:
a diode coupled between the second supply terminal and the first bias output of the bias generator; and
a capacitor coupled between the first bias output and the first input of the bias generator.

10. The circuit of claim 1, wherein the bias generator includes a charge transfer circuit coupled between the first bias output and the second bias output.

11. The circuit of claim 10, wherein the charge transfer circuit includes a common-drain bidirectional switch, the common-drain bidirectional switch including a third transistor having a third gate and a third source, and a fourth transistor having a fourth gate and a fourth source.

12. The circuit of claim 11, wherein the bias generator includes:
a third driver having a third bias terminal, a third reference terminal, and a third driver output, the third reference terminal coupled to the first input, the third bias terminal coupled to the first bias output, and the third driver output coupled to the third gate of the third transistor through a first capacitor; and
a fourth driver having a fourth bias terminal, a fourth reference terminal, and a fourth driver output, the fourth reference terminal coupled to the second input, the fourth bias terminal coupled to the second bias output, and the fourth driver output coupled to the fourth gate of the fourth transistor through a capacitor.

13. The circuit of claim 10, wherein the bias generator includes:
a first capacitor or a first voltage source coupled between the first input and the first bias output;
a first startup circuit coupled between the first bias output and the second bias output;
a second capacitor or a second voltage source coupled between the second input and the second bias output; and
a second startup circuit coupled between the second bias output and the first bias output.

14. The circuit of claim 13, wherein the first startup circuit includes:
a common-drain bidirectional switch having a first switch terminal and a second switch terminal, the first switch terminal coupled to the first bias output; and
a source follower coupled between the second switch terminal of the common-drain bidirectional switch and the second bias output.

15. The circuit of claim 14, wherein the common-drain bidirectional switch includes an enhancement-mode transistor and a depletion-mode transistor having a gate terminal coupled to the second input of the bias generator.

16. The circuit of claim 10, wherein the bias generator includes:
a voltage source including a positive terminal and a negative terminal, the negative terminal coupled to the first input;
a first capacitor coupled between the first input and the first bias output;
a first source follower coupled between the positive terminal of the voltage source and the first bias output;
a second capacitor coupled between the second input the second bias output;
a common-drain bidirectional switch including a first switch terminal and a second switch terminal, the first switch terminal coupled to the positive terminal of the voltage source; and
a second source follower coupled between the second switch terminal and the second bias output.

17. The circuit of claim 10, wherein:
the bias generator includes:
a first capacitor or a first voltage source coupled between the first input and the first bias output; and
a second capacitor or a second voltage source coupled between the second input and the second bias output; and
the charge transfer circuit includes:
a first bidirectional switch and a first source follower coupled between the first bias output and the second bias output, the first bidirectional switch coupled to the first bias output, and the first source follower coupled to the second bias output; and
a second bidirectional switch and a second source follower coupled between the first bias output and the second bias output, the second bidirectional switch coupled to the second bias output, and the second source follower coupled to the first bias output.

18. The circuit of claim 17, wherein:
the first bidirectional switch includes an enhancement-mode transistor and a depletion-mode transistor;
the enhancement-mode transistor includes a first gate terminal coupled to the first driver output via a third capacitor; and
the depletion-mode transistor includes a second gate terminal coupled to the second input of the bias generator.

19. The circuit of claim 10, wherein:
the bias generator includes:
a voltage source coupled between the first input and the first bias output; and
a first capacitor coupled between the second input and the second bias output; and
the charge transfer circuit includes a common-drain bidirectional switch and a source follower coupled between the first bias output and the second bias output, the common-drain bidirectional switch coupled to the first bias output, and the source follower coupled to the second bias output.

20. The circuit of claim 19, wherein:
the charge transfer circuit includes a third driver having a third bias terminal, a third reference terminal, and a third driver output, the third bias terminal coupled to the first bias output, and the third reference terminal coupled to the first input; and
the common-drain bidirectional switch includes an enhancement-mode transistor and a depletion-mode transistor, the enhancement-mode transistor having a first gate terminal coupled to the third driver output via a second capacitor, and the depletion-mode transistor having a second gate terminal coupled to the second input.

21. A circuit comprising:
a pair of transistors having a common drain, a first source, a second source, a first gate, and a second gate;
a first driver having a first bias terminal, a first reference terminal, a first driver input, and a first driver output, the first reference terminal coupled to the first source, and the first driver output coupled to the first gate;
a second driver having a second bias terminal, a second reference terminal, a second driver input, and a second driver output, the second reference terminal coupled to the second source, and the second driver output coupled to the second gate; and
a bias generator having a first input, a second input, a first bias output, and a second bias output, the first input coupled to the first source, the second input coupled to the second source, the first bias output coupled to the first bias terminal, and the second bias output coupled to the second bias terminal, wherein the bias generator is configurable to generate, based on a supply voltage, a first bias voltage at the first bias output and a second bias voltage at the second bias output.

22. A circuit comprising:
a first input port;
a first output port;
a second output port;
a first bidirectional switch coupled between the first input port and the first output port, the first bidirectional switch including a first switch driver, a second switch driver, and a first bias generator configurable to generate, based on a first supply voltage, a first bias voltage for the first switch driver and a second bias voltage for the second switch driver; and
a second bidirectional switch coupled between the first input port and the second output port, the second bidirectional switch including a third switch driver, a fourth switch driver, and a second bias generator configurable to generate, based on a second supply voltage, a third bias voltage for the third switch driver and a fourth bias voltage for the fourth switch driver.

23. The circuit of claim 22, further comprising:
a second input port;
a third bidirectional switch coupled between the second input port and the first output port, the third bidirectional switch including a fifth switch driver, a sixth switch driver, and a third bias generator configurable to generate, based on the first supply voltage, a fifth bias voltage for the fifth switch driver and a sixth bias voltage for the sixth switch driver; and
a fourth bidirectional switch coupled between the second input port and the second output port, the fourth bidirectional switch including a seventh switch driver, an eighth switch driver, and a fourth bias generator configurable to generate, based on the second supply voltage, a seventh bias voltage for the seventh switch driver and an eighth bias voltage for the eighth switch driver.
